(19) United States
(12) Patent Application Publication
(10) Pub. No.: US 2026/0255755 A1
(43) Pub. Date: Aug. 27, 2026

(54) DISPLAY APPARATUS INCLUDING CRACK DETECTION CIRCUIT AND ELECTRONIC DEVICE INCLUDING THE SAME

(71) Applicant: SAMSUNG DISPLAY CO., LTD., YONGIN-SI (KR)

(72) Inventors: Minjoo Kim, YONGIN-SI (KR); Minwoo Byun, YONGIN-SI (KR); Chaehan Hyun, YONGIN-SI (KR)

(21) Appl. No.: 19/448,603

(22) Filed: Jan. 14, 2026

(30) Foreign Application Priority Data
Feb. 24, 2025 (KR) 10-2025-0023878

(51) Int. Cl. H10H 29/49; G09G 3/32; H10D 86/40; H10D 86/60; H10H 29/32

(52) U.S. Cl. CPC H10H 29/49; G09G 3/32; H10D 86/443; H10D 86/60; H10H 29/32; G09G 2300/0814; G09G 2330/021

(57) ABSTRACT

A display apparatus includes a substrate including a display area and a peripheral area proximate to the display area. First data lines are disposed in the display area and second data lines are disposed between neighboring pairs of the first data lines. A first crack detection line is disposed in the peripheral area, and includes a first subline and a second subline. A first connection line is electrically connected to the first subline. A first voltage line is electrically connected to the first connection line. A second voltage line is electrically connected to the second subline. A crack detection circuit is configured to electrically connect the first data lines to the first voltage line and electrically connect the second data lines to the second voltage line. A power management circuit supplies a detection voltage having a negative value to the first connection line.

### CROSS-REFERENCE TO RELATED APPLICATION

This application claims priority under 35 U.S.C. §119 to Korean Patent Application No. 10-2025-0023878, filed on February 24, 2025, in the Korean Intellectual Property Office, the disclosure of which is incorporated by reference herein in its entirety.

### TECHNICAL FIELD

The present disclosure relates to a display apparatus and, more specifically, to a display apparatus including a crack detection circuit and an electronic device including the same.

### DISCUSSION OF THE RELATED ART

In recent years, display devices have become thinner and have been used in various electronic devices. As the scope of use of display apparatuses expands, the demand for high-quality display apparatuses is increasing. In order to reduce the area of a non-display area visible from a front side of an electronic device, often referred to as a bezel region, a portion of the display apparatus may be bent so as to reduce the visible size of the bezel when mounted on the electronic device. Alternatively, various forms of display apparatuses, such as flexible display apparatuses that can be folded or rolled, and electronic devices including the display apparatuses have been designed.

### SUMMARY

A display apparatus includes a substrate including a display area in which a plurality of pixels are disposed and a peripheral area proximate to the display area. First data lines are disposed in the display area and second data lines are disposed between neighboring pairs of the first data lines. A first crack detection line is disposed in the peripheral area, extending along a portion of an edge of the substrate, and including a first subline and a second subline. A first connection line is electrically connected to the first subline. A first voltage line is electrically connected to the first connection line. A second voltage line is electrically connected to the second subline. A crack detection circuit is configured to electrically connect the first data lines to the first voltage line and electrically connect the second data lines to the second voltage line. A power management circuit is configured to supply a detection voltage having a negative value to the first connection line.

Each of the plurality of pixels may include a pixel circuit and a light-emitting diode electrically connected to the pixel circuit. The pixel circuit may include a first transistor electrically connected between a driving voltage line and the light-emitting diode, a second transistor electrically connected between one of the first data lines and the second data lines and a gate of the first transistor, a third transistor electrically connected between a reference voltage line and the gate of the first transistor, a fourth transistor electrically connected between an initializing voltage line and the light-emitting diode, a fifth transistor electrically connected between the driving voltage line and a first terminal of the first transistor, a sixth transistor electrically connected between the light-emitting diode and a second terminal of the first transistor, a first capacitor electrically connected between the gate of the first transistor and the second terminal of the first transistor, and a second capacitor electrically connected between the driving voltage line and the second terminal of the first transistor.

The first transistor may be an n-type transistor.

The fifth transistor may be a p-type transistor.

The sixth transistor may be a p-type transistor.

The first transistor may be a metal oxide thin-film transistor.

The fifth transistor and the sixth transistor may each be silicon thin-film transistors.

An initializing voltage less than or equal to the detection voltage may be applied to the initializing voltage line.

The power management circuit may be configured to supply a first reference voltage to the reference voltage line in a normal mode and to supply a second reference voltage to the reference voltage line in a crack detection mode, and the second reference voltage may be greater than the first reference voltage.

The first crack detection line may have serpentine patterns.

The crack detection circuit may include a gate signal line configured to transmit the crack detection signal. First detection transistors may be electrically connected between the first data lines and the first voltage line. Second detection transistors may be electrically connected between the second data lines and the second voltage line. A gate of each of the first detection transistors and the second detection transistors may be electrically connected to the gate signal line.

The peripheral area may include a bending region and a subregion spaced apart from the display area with the bending region interposed therebetween. The display apparatus may further include third data lines disposed in the display area and disposed between the first data lines. A second crack detection line may be disposed in the bending region and may have a first end and a second end. A third voltage line may be electrically connected to the first end of the second crack detection line. The crack detection circuit may be configured to electrically connect the third data lines to the third voltage line. The power management circuit may be configured to supply the detection voltage to the second end of the second crack detection line.

The crack detection circuit may include a gate signal line configured to transmit the crack detection signal. First detection transistors may be electrically connected between the first data lines and the first voltage line. Second detection transistors may be electrically connected between the second data lines and the second voltage line. Third detection transistors may be electrically connected between the third data lines and the third voltage line. A gate of each of the first detection transistors, the second detection transistors, and the third detection transistors may be electrically connected to the gate signal line.

A display apparatus includes a substrate including a display area in which a plurality of pixels are disposed and a peripheral area proximate to the display area. First data lines are disposed in the display area and second data lines are disposed between neighboring pairs of the first data lines. A first crack detection line is disposed in the peripheral area, extending along a portion of an edge of the substrate, and including a first subline and a second subline. A first connection line is electrically connected to the first subline. A first voltage line is electrically connected to the first connection line. A second voltage line is electrically connected to the second subline. A crack detection circuit electrically connects the first data lines to the first voltage line and electrically connects the second data lines to the second voltage line. The first connection line is grounded.

Each of the plurality of pixels may include a pixel circuit and a light-emitting diode electrically connected to the pixel circuit. The pixel circuit may include a first transistor electrically connected between a driving voltage line and the light-emitting diode, a second transistor electrically connected between one of the first data lines and the second data lines and a gate of the first transistor, a third transistor electrically connected between a reference voltage line and the gate of the first transistor, a fourth transistor electrically connected between an initializing voltage line and the light-emitting diode, a fifth transistor electrically connected between the driving voltage line and a first terminal of the first transistor, a sixth transistor electrically connected between the light-emitting diode and a second terminal of the first transistor, a first capacitor electrically connected between the gate of the first transistor and the second terminal of the first transistor, and a second capacitor electrically connected between the driving voltage line and the second terminal of the first transistor.

The first transistor may be an n-type transistor.

The fifth transistor may be a p-type transistor.

The display apparatus may further include a power management circuit configured to supply a first reference voltage to the reference voltage line in a normal mode and supply a second reference voltage to the reference voltage line in a crack detection mode. The second reference voltage may be greater than the first reference voltage.

The crack detection circuit may include a gate signal line configured to transmit the crack detection signal, first detection transistors electrically connected between the first data lines and the first voltage line, and second detection transistors electrically connected between the second data lines and the second voltage line. A gate of each of the first detection transistors and the second detection transistors may be electrically connected to the gate signal line.

An electronic device includes a display apparatus configured to display an image, based on an image data signal. A memory stores an application. A processor is configured to execute the application and transmit the image data signal and a control signal to the display apparatus. The display apparatus includes a substrate including a display area in which a plurality of pixels are disposed and a peripheral area proximate to the display area. First data lines are disposed in the display area and second data lines are disposed between neighboring pairs of the first data lines. A first crack detection line is disposed in the peripheral area, extending along a portion of an edge of the substrate, and including a first subline and a second subline. A first connection line is electrically connected to the first subline. A first voltage line is electrically connected to the first connection line. A second voltage line is electrically connected to the second subline. A crack detection circuit is configured to electrically connect the first data lines to the first voltage line and electrically connect the second data lines to the second voltage line. A power management circuit is configured to supply a voltage for driving the plurality of pixels. The first connection line is configured to be grounded or to be supplied with a detection voltage having a negative value.

Each of the plurality of pixels may include a pixel circuit and a light-emitting diode electrically connected to the pixel circuit. The pixel circuit may include a first transistor electrically connected between a driving voltage line and the light-emitting diode, and a second transistor electrically connected between one of the first data lines and the second data lines and a gate of the first transistor. The first transistor may be an n-type transistor.

### BRIEF DESCRIPTION OF THE DRAWINGS

The above and other aspects and features of certain embodiments of the disclosure will be more apparent from the following description taken in conjunction with the accompanying drawings, in which:

FIG. 1 is a schematic perspective view of a display apparatus according to an embodiment;

FIG. 2 is a schematic plan view of a display panel according to an embodiment;

FIG. 3 is a schematic side view of a display panel according to an embodiment;

FIG. 4 is a schematic plan view of a display panel according to an embodiment;

FIGS. 5A and 5B are equivalent circuit diagrams of light-emitting diodes and pixel circuits according to an embodiment;

FIG. 6 is a schematic cross-sectional view of a display panel according to an embodiment;

FIG. 7 is a schematic plan view of a region I of the display panel of FIG. 4;

FIG. 8 is a schematic plan view of a region II of the display panel of FIG. 4;

FIG. 9 is a schematic view of a display apparatus according to an embodiment;

FIGS. 10A and 10B are schematic signal diagrams illustrating an operation of a pixel circuit according to an embodiment;

FIG. 11 is a schematic signal diagram illustrating an operation of a crack detection circuit according to an embodiment;

FIG. 12 is a schematic block diagram of an electronic device according to an embodiment; and

FIGS. 13 through 15 are schematic perspective views of electronic devices according to various embodiments.

### DETAILED DESCRIPTION

Reference will now be made in detail to embodiments, examples of which are illustrated in the accompanying drawings, wherein like reference numerals may refer to like elements throughout the specification and the drawings. In this regard, the present embodiments may have different forms and should not necessarily be construed as being limited to the descriptions set forth herein. Accordingly, the embodiments are merely described below, by referring to the figures, to explain aspects of the present description. As used herein, the term "and/or" includes any and all combinations of one or more of the associated listed items. Throughout the disclosure, the expression "at least one of a, b or c" indicates only a, only b, only c, both a and b, both a and c, both b and c, all of a, b, and c, or variations thereof.

As the disclosure allows for various changes and numerous embodiments, particular embodiments will be illustrated in the drawings and described in detail in the written description. Hereinafter, effects and features of the disclosure and a method for accomplishing them will be described more fully with reference to the accompanying drawings, in which embodiments of the disclosure are shown. The disclosure may, however, be embodied in many different forms and should not necessarily be construed as limited to the embodiments set forth herein.

One or more embodiments will be described below in more detail with reference to the accompanying drawings. Those components that are the same as or are in correspondence with each other may be referred to herein by the same reference numeral within all of the figures, and to the extent that an element is not described in detail with respect to a particular figure, it may be understood that the element is at least similar to a corresponding element that has been described elsewhere within the present disclosure.

It will be understood that although the terms "first," "second," etc. may be used herein to describe various components, these components should not necessarily be limited by these terms. These components are used to distinguish one component from another.

As used herein, the singular forms "a," "an," and "the" are intended to include the plural forms as well, unless the context clearly indicates otherwise.

The terms "comprises" and/or "comprising" used herein specify the presence of stated features or components, but do not necessarily preclude the presence or addition of one or more other features or components.

When a layer, region, or component is referred to as being "formed on" another layer, region, or component, it can be directly or indirectly formed on the other layer, region, or component. That is, for example, intervening layers, regions, or components may be present.

When a layer, region, or component is referred to as being "connected" or "coupled" to another layer, region, or component, it can be directly connected or coupled to the other layer, region, or/and component or intervening layers, regions, or components may be present. For example, when a layer, region, or component is referred to as being "electrically connected" or "electrically coupled" to another layer, region, or component, it can be directly electrically connected or coupled to the other layer, region, and/or component or intervening layers, regions, or components may be present.

In the present specification, "A and/or B" represents A or B, or A and B. The expression "at least one of A and B" indicates only A, only B, both A and B, or variations thereof.

An x direction, a y direction, and a z direction used herein are not necessarily limited to directions along three axes of a Cartesian coordinate system, and may be interpreted in a broader sense. For example, the x direction, the y direction, and the z direction may be perpendicular to one another, or may represent different directions that are not necessarily perpendicular to one another.

In the present specification, when referred to "a plan view", it means when an object is viewed from above (e.g., when an object is viewed in a direction perpendicular to an upper surface of a substrate), and when referred to "a cross-sectional view", it means when a cross section formed by vertically cutting an object is viewed from the side.

In the present specification, a first component "overlapping" a second component refers to the first component being located above or below the second component and accordingly at least partially overlapping the second component.

In the present specification, "ON" or “on” used in association with an element state may be referred to as an activated state of an element, and "OFF" or “off” may be referred to as an inactivated state of an element. "ON" or “on” used in association with a signal received by an element may be referred to as a signal for activating the element, and "OFF" or “off” may be referred to as a signal for inactivating the element. An element may be activated by a high-level voltage or a low-level voltage. For example, a P-type transistor (P-channel transistor) is activated by a low-level voltage, and an N-type transistor (N-channel transistor) is activated by a high-level voltage. Therefore, it should be understood that an "ON" voltage for a P-type transistor and an “ON” voltage for an N-type transistor have opposite (high versus low) voltage levels.

When a certain embodiment may be implemented differently, a specific process order may be performed differently from the described order. For example, two consecutively described processes may be performed substantially at the same time or performed in an order opposite to the described order.

While each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like.

During production of display devices, cracks may occur in a display panel when a display device including the display panel is moved or handled. These cracks may allow ambient moisture and other contaminants to reach a light-emitting diode, leading to degradation of display quality. One or more embodiments include a display apparatus including a crack detector for detecting a crack in a display panel and an electronic device including the display apparatus. However, aspects of embodiments are not necessarily limited thereto, and the above characteristics do not necessarily limit the scope of embodiments according to the disclosure.

Embodiments of the present disclosure relate to a sophisticated display apparatus designed for modern electronic devices, particularly those utilizing flexible, foldable, or bendable displays. For example, the display apparatus includes a substrate with a central display area where numerous pixels are disposed, surrounded by a peripheral area that accommodates various supporting circuits and wiring. The display area may include an array of pixel circuits that each control a light-emitting diode, relying on complex transistor configurations to modulate brightness and color. The system may be able to operate in normal display mode or switch to a crack detection mode, depending on signals from the device’s processor and a power management circuit.

A novel crack detection system may be integrated directly into the display apparatus architecture. This system may include crack detection lines that trace portions of the substrate’s edges and bending regions. These detection lines may be formed as serpentine or curved patterns, engineered to register changes in electrical resistance or voltage when a physical crack occurs in the panel. When the display apparatus is in crack detection mode, the crack detection circuit may reroute electrical connections, supplying specific voltages through these crack detection lines and monitor voltage shifts that indicate damage. A bright line or colored emission from certain pixels may then signal the presence and location of cracks, thus allowing precise diagnosis without dismantling the device.

This versatility may be applied to different display technologies, supporting configurations where key transistors are either metal-oxide thin-film transistors or silicon-based transistors, depending on design requirements like mobility and leakage current. This architecture may ensure the display apparatus can maintain slim profiles suitable for mobile devices, wearables, automotive displays, and other advanced applications, all while embedding a reliable, real-time mechanism for identifying cracks that could compromise display quality or device integrity. As a result, manufacturers can enhance the durability and reliability of flexible and foldable electronics, responding proactively to structural failures before they lead to broader device malfunctions.

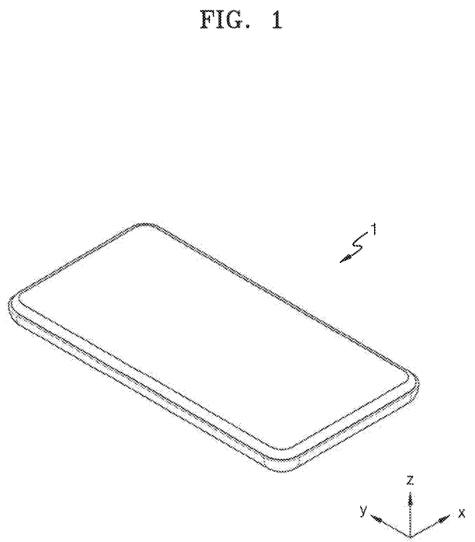

FIG. 1 is a perspective view of a display apparatus 1 according to an embodiment.

Referring to FIG. 1, the display apparatus 1, according to an embodiment, displays a moving picture or a still image, and thus may be used as a display screens for various electronic devices, such as not only portable electronic apparatuses (such as mobile phones, smartphones, tablet computers, mobile communication terminals, electronic notebooks, electronic books, portable multimedia players (PMPs), navigation devices, and ultra mobile PCs (UMPCs)) but also televisions, notebook/laptop computers, computer monitors, digital billboards, and Internet of things (IoT) devices. The display apparatus 1, according to an embodiment, may be used in wearable devices, such as smart watches, watch phones, glasses-type displays, and head mounted displays (HMDs). The display apparatus 1, according to an embodiment, may be used as dashboards of automobiles, center information displays (CIDs) of the center fasciae or dashboards of automobiles, room mirror displays that replace the side mirrors of automobiles, and displays of electronic devices disposed on the rear sides of front seats to serve as entertainment devices for back seat passengers of automobiles.

For convenience of explanation, the display apparatus 1, according to an embodiment, is illustrated as being used in a smartphone. The display apparatus 1 may have a substantially rectangular shape in a plan view. For example, the display apparatus 1 may have a rectangular planar shape having a pair of shorter sides extending in a first direction (x direction) and a pair of longer sides extending in a second direction (y direction). Corners between the shorter sides in the first direction (x direction) and the longer sides in the second direction (y direction) may be rounded to have a certain curvature, or may have right angles. The planar shape of the display apparatus 1 is not necessarily limited to a rectangle, and may be any other polygon, an oval, or an irregular shape.

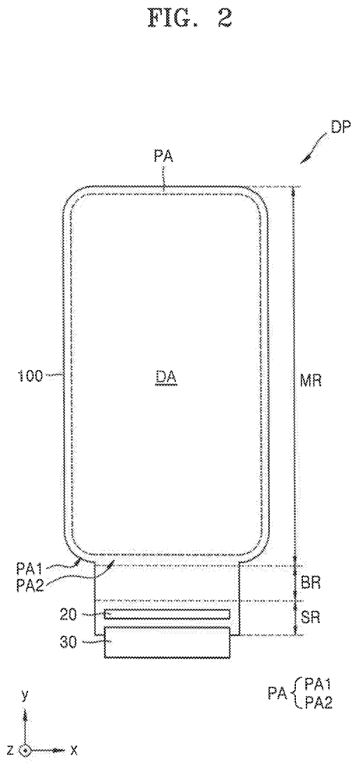

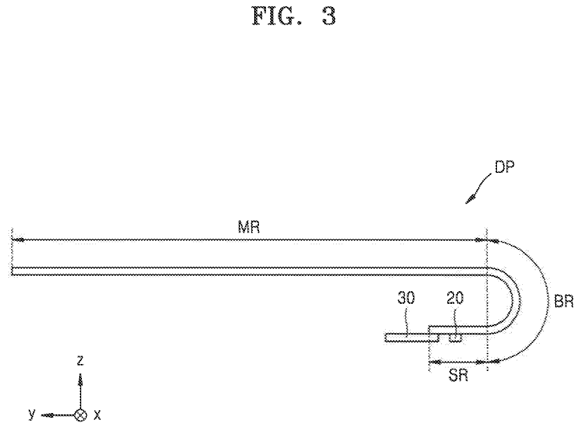

FIG. 2 is a schematic plan view of a display panel DP according to an embodiment, and FIG. 3 is a schematic side view of the display panel DP according to an embodiment.

Referring to FIGS. 2 and 3, the display apparatus 1 (see FIG. 1) may include the display panel DP and a display circuit board 30. The display panel DP may include a display area DA and a peripheral area PA surrounding the display area DA on at least two sides thereof, and may thus be said to be proximate to the display area DA. A shape of the display panel DP of FIG. 2 may be substantially the same as a shape of a substrate 100 included in the display panel DP, in a plan view. That the display panel DP includes the display area DA and the peripheral area PA outside the display area DA may represent that the substrate 100 includes the display area DA and the peripheral area PA outside the display area DA.

The display area DA, in which an image is displayed, may include a plurality of pixels disposed therein. The display area DA may have any of various shapes such as a circular shape, an oval shape, a polygonal shape, and a particular figure shape. For example, as shown in FIG. 2, the display area DA may have a substantially rectangular shape with rounded corners.

The peripheral area PA may be disposed outside of the display area DA. The peripheral area PA may include a first peripheral area PA1 surrounding at least a portion of the display area DA, and a second peripheral area PA2 extending downwards (in a -y direction) from a lower (-y direction) boundary of the display area DA. A width of the second peripheral area PA2 in a first direction (x direction) may be less than a width of the display area DA in the first direction. Accordingly, at least a portion of the second peripheral area PA2 may be bent to at least a noticeable extent without cracking or otherwise sustaining damage.

The display panel DP (or the substrate 100) may include a main region MR, a bending region BR outside of, and proximate to, the main region MR, and a subregion SR spaced apart from the main region MR with the bending region BR interposed therebetween. The bending region BR may extend in the first direction (x direction) from one edge of the substrate 100 to the other edge. The main region MR may be disposed on an upper side (+y direction) of the bending region BR, and the subregion SR may be disposed on a lower side (-y direction) of the bending region BR.

The main region MR may overlap the display area DA and a portion of the peripheral area PA. The subregion SR and the bending region BR may overlap a portion of the peripheral area PA. For example, the subregion SR and the bending region BR may overlap the second peripheral area PA2.

As illustrated in FIG. 3, the display panel DP may be bent in the bending region BR such that at least a portion of the subregion SR may overlap the main region MR in a view in a third direction (z direction). Although FIG. 3 illustrates that a non-display area of the display panel DP is bent, the disclosure is not necessarily limited thereto. According to an embodiment, the display panel DP may be a foldable display panel in which the display area DA is bent about a bending axis extending across the display area DA. According to an embodiment, the display panel DP might not be bendable.

A data driver 20 may be disposed in the subregion SR of the display panel DP. The data driver 20 may be disposed on the display panel DP in the form of an integrated circuit. For example, the data driver 20 may be a data driving integrated circuit that generates a data signal.

The display circuit board 30 may be attached to an end of the subregion SR of the display panel DP. The display circuit board 30 may be electrically connected to the data driver 20 via a pad of the subregion SR of the display panel DP.

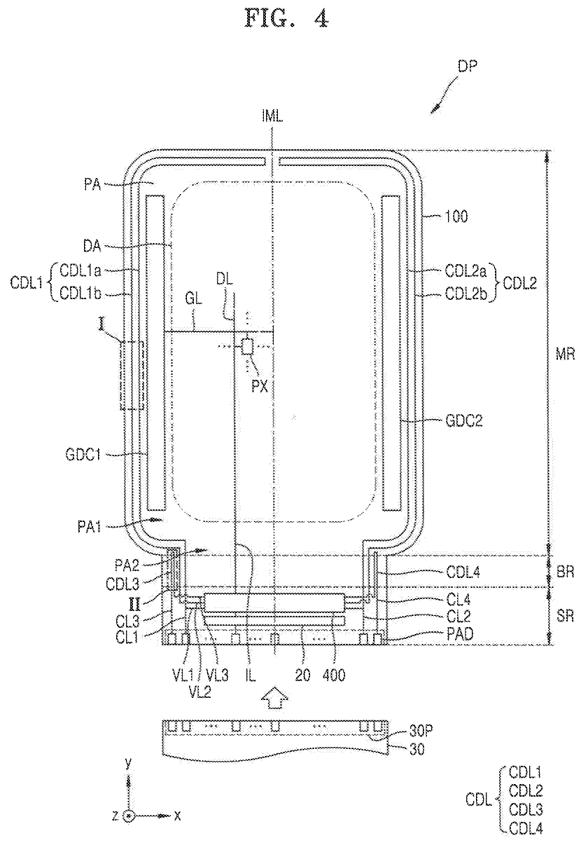

FIG. 4 is a schematic plan view of the display panel DP according to an embodiment.

Referring to FIG. 4, the display panel DP may include the substrate 100. Components that constitute the display panel DP may be disposed on the substrate 100.

The substrate 100 may include glass, a metal, and/or a polymer resin. For example, the substrate 100 may include polymer resin such as polyethersulphone, polyacrylate, polyetherimide, polyethylene naphthalate, polyethylene terephthalate, polyphenylene sulfide, polyarylate, polyimide, polycarbonate, or cellulose acetate propionate. The substrate 100 may have a multi-layered structure including two layers each including the aforementioned polymer resin and an inorganic material layer interposed between the two layers.

The substrate 100 may include the display area DA and the peripheral area PA proximate to (e.g., surrounding) the display area DA. A plurality of pixels PX may be disposed in the display area DA. The display area DA may provide an image by using light emitted from the plurality of pixels PX. A pixel PX used herein refers to a subpixel that emits red light, green light, or blue light. Each of the plurality of pixels PX may include a pixel circuit and a light-emitting diode electrically connected to the pixel circuit. For example, the display area DA may be defined an area wherein the light-emitting diodes are disposed. The plurality of pixels PX may be disposed in various structures, such as in a stripe structure, a mosaic structure, a PenTile^{TM} (A PenTile^{TM} arrangement is an arrangement of luminous areas manufactured by SAMSUNG in which some subpixels are shared between adjacent pixels to reduce the total number of subpixels used), or a delta structure.

The peripheral area PA may include the first peripheral area PA1 and the second peripheral area PA2. A first gate driving circuit GDC1, a second gate driving circuit GDC2, and wiring may be disposed in the first peripheral area PA1. The wiring may include a common voltage supply line, a first crack detection line CDL1, and a second crack detection line CDL2. The data driver 20, a pad portion PAD, a crack detection circuit 400, and wiring may be disposed in the second peripheral area PA2. The wiring may include a driving voltage supply line, first, second, and third voltage lines VL1, VL2, and VL3, a third crack detection line CDL3, a fourth crack detection line CDL4, and first, second, third, and fourth connection lines CL1, CL2, CL3, and CL4.

The first gate driving circuit GDC1 and the second gate driving circuit GDC2 may provide gate signals to the pixel circuits of the pixels PX through gate lines GL. The first gate driving circuit GDC1 and the second gate driving circuit GDC2 may be spaced apart from each other with the display area DA interposed therebetween. According to an embodiment, pixels PX disposed on a left (-x direction) side of an imaginary line IML passing through the center of the display area DA may be electrically connected to the first gate driving circuit GDC1, and pixels PX disposed on a right (+x direction) side of the imaginary line IML may be electrically connected to the second gate driving circuit GDC2. According to an embodiment, the second gate driving circuit GDC2 might not be included.

According to an embodiment, the first gate driving circuit GDC1 may include a light-emission control driving circuit that provides a light-emission control signal to the pixels PX through a light-emission control line. According to an embodiment, each of the first gate driving circuit GDC1 and the second gate driving circuit GDC2 may include a light-emission control driving circuit.

The data driver 20 may be disposed in a subregion SR. The data driver 20 may transmit data signals to the pixel circuits of the pixels PX via input lines IL and data lines DL electrically connected to the input lines IL.

The pad portion PAD may be disposed on a lower (-y direction) side of the subregion SR. The pad portion PAD may include a plurality of pads. The plurality of pads may be exposed without being covered by an insulating layer, and may be electrically connected to the display circuit board 30. For example, a pad portion 30P of the display circuit board 30 may be electrically connected to the pad portion PAD of the display panel DP.

A crack detection line CDL may include the first crack detection line CDL1, the second crack detection line CDL2, the third crack detection line CDL3, and the fourth crack detection line CDL4. The first crack detection line CDL1 and the second crack detection line CDL2 may be disposed in the first peripheral area PA1, and may extend along a portion of the edge of the substrate 100. The third crack detection line CDL3 and the fourth crack detection line CDL4 may be disposed in the second peripheral area PA2, for example, in the bending region BR of the substrate 100.

The first crack detection line CDL1 may include a first subline CDL1a and a second subline CDL1b. The first subline CDL1a may extend along a left (-x direction) edge of the substrate 100 and a portion of an upper (+y direction) edge of the substrate 100. The second subline CDL1b may be disposed between the first subline CDL1a and the display area DA in a plan view. The first subline CDL1a and the second subline CDL1b may be electrically connected to each other at a center of the upper (+y direction) side of the substrate 100.

The second crack detection line CDL2 may include a third subline CDL2a and a fourth subline CDL2b. The third subline CDL2a may extend along a right (+x direction) edge of the substrate 100 and a portion of the upper (+y direction) edge of the substrate 100. The fourth subline CDL2b may be disposed between the third subline CDL2a and the display area DA in a plan view. The third subline CDL2a and the fourth subline CDL2b may be electrically connected to each other at the center of the upper (+y direction) side of the substrate 100. The first crack detection line CDL1 and the second crack detection line CDL2 may have a roughly line-symmetrical shape, based on an imaginary line IML that passes through the center of the substrate 100 and extends in the second direction (y direction).

The first subline CDL1a of the first crack detection line CDL1 may be electrically connected to the pad portion PAD via the first connection line CL1. The third subline CDL2a of the second crack detection line CDL2 may be electrically connected to the pad portion PAD via the second connection line CL2. The second subline CDL1b of the first crack detection line CDL1 and the fourth subline CDL2b of the second crack detection line CDL2 may be electrically connected to the second voltage line VL2. The first connection line CL1 and the second connection line CL2 may be electrically connected to the first voltage line VL1.

A power management circuit may supply a detection voltage to the first crack detection line CDL1, the second crack detection line CDL2, and the first voltage line VL1 through the first connection line CL1 and the second connecting line CL2. According to an embodiment, the detection voltage may be a low level voltage having a negative value. For example, the detection voltage may be a gate low voltage that turns off an N-type transistor. The gate low voltage may be selected as needed in the range of about -10 V to about -1 V. According to an embodiment, the detection voltage may be a ground voltage. When no cracks occur, the second voltage line VL2 may receive the detection voltage via the first crack detection line CDL1 and the second crack detection line CDL2. When a crack occurs in the first crack detection line CDL1 or the second crack detection line CDL2, a voltage of the second voltage line VL2 may be different from the detection voltage. For example, the voltage of the second voltage line VL2 may have a higher voltage than the detection voltage.

Each of the third crack detection line CDL3 and the fourth crack detection line CDL4 may have a curved shape that extends from the subregion SR to the main region MR via the bending region BR and then extends over the bending region BR to the subregion SR. The third crack detection line CDL3 may be disposed on the left side (-x direction) of the display panel DP, and the fourth crack detection line CDL4 may be disposed on the right side (+x direction) of the display panel DP.

A first end of the third crack detection line CDL3 may be electrically connected to the pad portion PAD via the third connection line CL3, and a second end of the third crack detection line CDL3 may be connected to the third voltage line VL3. A first end of the fourth crack detection line CDL4 may be electrically connected to the pad portion PAD via the fourth connection line CL4, and a second end of the fourth crack detection line CDL4 may be electrically connected to the third voltage line VL3.

The power management circuit may supply a detection voltage to the third crack detection line CDL3 and the fourth crack detection line CDL4 through the third connection line CL3 and the fourth connecting line CL4. When no cracks occur, the third voltage line VL3 may receive the detection voltage via the third crack detection line CDL3 and the fourth crack detection line CDL4. When a crack occurs in the third crack detection line CDL3 or the fourth crack detection line CDL4, a voltage of the third voltage line VL3 may be different from the detection voltage. For example, the voltage of the third voltage line VL3 may have a higher voltage than the detection voltage.

The crack detection circuit 400 may be disposed in the subregion SR. The crack detection circuit 400 may be electrically connected to the data lines DL and the first through third voltage lines VL1 through VL3. In a crack detection mode, the crack detection circuit 400 may electrically connect each of the data lines DL to one of the first through third voltage lines VL1 through VL3, according to a crack detection signal that is provided by a signal generator.

Pixels PX to which a detection voltage is applied via the data line DL may emit black light. That a pixel PX emits black light mans that, because a magnitude of a driving current output by a driving transistor during a light-emission period of the pixel PX is small, the light-emitting diode does not emit light or emits light very weakly. For example, when the detection voltage is applied to the data line DL, a gate-source voltage of a driving transistor of the pixel PX may be 0 V or have a negative value less than 0 V. Thus, as used herein, the phrase “emits black light” may be understood to mean that the pixels are black and that no light or nearly no light is emitted therefrom.

Because the first voltage line VL1 is directly connected to the first connection line CL1 and the second connection line CL2 and receives a detection voltage, pixels PX whose data lines DL are electrically connected to the first voltage line VL1 may emit black light. When the first crack detection line CDL1 and the second crack detection line CDL2 are not damaged, pixels PX whose data lines DL are electrically connected to the second voltage line VL2 may equally emit black light. When the first crack detection line CDL1 or the second crack detection line CDL2 is damaged by cracks, etc., a voltage transmitted to the second voltage line VL2 may be greater than the detection voltage. Accordingly, the pixels PX of which a data line DL is electrically connected to the second voltage line VL2 may emit light in a color other than black (e.g., may emit at least some light), so that a bright line may be displayed in the display area DA. Based on a light-emission state of the pixels PX of which a data line DL is electrically connected to the second voltage line VL2, it may be determined whether an edge portion of the display panel DP is damaged.

Similarly, when the third crack detection line CDL3 and the fourth crack detection line CDL4 are not damaged, pixels PX whose data lines DL are electrically connected to the third voltage line VL3 may emit black light. When the third crack detection line CDL3 or the fourth crack detection line CDL4 is damaged by cracks, etc., a voltage transmitted to the third voltage line VL3 may be greater than the detection voltage. Accordingly, the pixels PX of which a data line DL is electrically connected to the third voltage line VL3 may emit light in a color other than black, so that a bright line may be displayed in the display area DA. Based on a light-emission state of the pixels PX of which a data line DL is electrically connected to the third voltage line VL3, it may be determined whether the bending region BR of the display panel DP is damaged.

According to an embodiment, a left side (in a -x direction) and a right side (in a +x direction) of the second voltage line VL2 may be electrically separated based on the imaginary line IML passing through the center of the display panel DP. Therefore, it may be possible to determine whether a crack has occurred in the first crack detection line CDL1 or the second crack detection line CDL2 for example, determine a location of the crack. Likewise, a left side (in the -x direction) and a right side (in the +x direction) of the third voltage line VL3 may be electrically separated based on the imaginary line IML. Therefore, it may be possible to determine whether a crack has occurred in the third crack detection line CDL3 or the fourth crack detection line CDL4 for example, determine a location of the crack.

The display circuit board 30 transmits a signal of a processor or power supplied by a power module to the display panel DP. According to an embodiment, the power management circuit that supplies power to components of the display panel DP may be on the display circuit board 30, as a portion of the power module. The processor may supply control signals to the first gate driving circuit GDC1, the second gate driving circuit GDC2, and the data driver 20 via the display circuit board 30. The power management circuit may supply signals and/or voltages for driving pixels PX, according to the control signals. The power management circuit may provide a driving voltage ELVDD and a common voltage ELVSS to the driving voltage supply line and the common voltage supply line, respectively, via corresponding pads of the pad portion PAD. The power management circuit may transmit a detection voltage to the first, second, third, and fourth crack detection lines CDL1, CDL2, CDL3, and CDL4 and the first voltage line VL1 via the corresponding pads of the pad portion PAD.

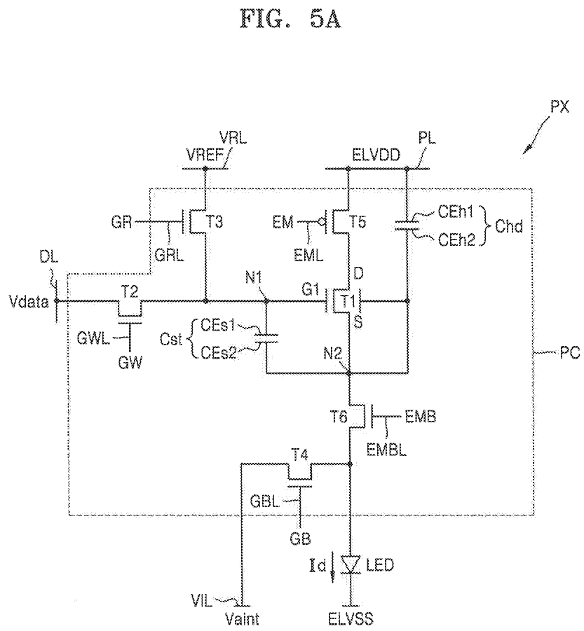

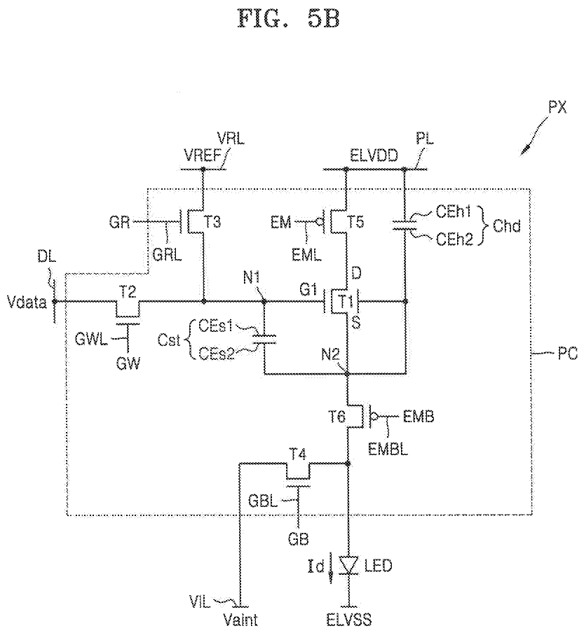

FIGS. 5A and 5B are equivalent circuit diagrams of light-emitting diodes LED and pixel circuits PC according to an embodiment.

Referring to FIGS. 5A and 5B, one pixel PX may include a pixel circuit PC, and a light-emitting diode LED electrically connected to the pixel circuit PC. The pixel circuit PC may include a plurality of transistors and a plurality of capacitors. According to an embodiment, the pixel circuit PC may include first, second, third, fourth, fifth, and sixth transistors T1, T2, T3, T4, T5, and T6, a storage capacitor Cst, and a hold capacitor Chd. The first transistor T1 may be a driving transistor configured to output a driving current Id corresponding to a data signal, and the second, third, fourth, fifth, and sixth transistors T2, T3, T4, T5, and T6 may be switching transistors configured to transmit signals. A first terminal (first electrode) of each of the first, second, third, fourth, fifth, and sixth transistors T1, T2, T3, T4, T5, and T6 may be a source or a drain, and a second terminal (second electrode) thereof may be a terminal different from the first terminal. For example, when the first terminal is a drain, the second terminal may be a source.

According to an embodiment, the first transistor T1 may be an n-channel MOSFET (NMOS) (hereinafter, referred to as an N-type transistor). At least one of the second, third, fourth, fifth, and sixth transistors T2, T3, T4, T5, and T6 may be a p-channel MOSFET (PMOS) (hereinafter, referred to as a P-type transistor), and the remaining transistors may be N-type transistors. For example, as illustrated in FIG. 5A, the fifth transistor T5 may be a P-type transistor, and the first, second, third, fourth, and sixth transistors T1, T2, T3, T4, and T6 may be N-type transistors. According to an embodiment, as illustrated in FIG. 5B, the fifth transistor T5 and the sixth transistor T6 may be P-type transistors, and the first, second, third, and fourth transistors T1, T2, T3, and T4 may be N-type transistors. Alternatively, the first, second, third, fourth, fifth, and sixth transistors T1, T2, T3, T4, T5, and T6 may be all N-type transistors.

The first transistor T1 may be a metal oxide thin-film transistor having a metal oxide semiconductor layer. At least one of the second, third, fourth, fifth, and sixth transistors T2, T3, T4, T5, and T6 may be a silicon thin-film transistor having a low-temperature polycrystalline silicon (LTPS) semiconductor layer, and the remaining ones of the second, third, fourth, fifth, and sixth transistors T2, T3, T4, T5, and T6 may be metal oxide thin-film transistors. For example, the fifth transistor T5 may include a semiconductor layer made of polycrystalline silicon having high reliability, and the first, second, third, fourth and sixth transistors T1, T2, T3, T4, and T6 may include metal oxide semiconductor layers each having a high carrier mobility and a low leakage current. According to an embodiment, the fifth transistor T5 and the sixth transistor T6 may include semiconductor layers made of polycrystalline silicon, and the first, second, third, and fourth transistors T1, T2, T3, and T4 may include metal oxide semiconductor layers.

The pixel circuit PC may be electrically connected to a gate line that transmits a signal to a gate of each of the first, second, third, fourth, fifth, and sixth transistors T1, T2, T3, T4, T5, and T6. For example, the pixel circuit PC may be connected to a scan line GWL configured to transmit a scan signal GW, an initialization gate line GBL configured to transmit an initialization signal GB, a reference gate line GRL configured to transmit a reference signal GR, a first light-emission control line EML configured to transmit a first light-emission control signal EM, a second light-emission control line EMBL configured to transmit a second light-emission control signal EMB, and a data line DL configured to transmit a data voltage Vdata. The pixel circuit PC may also be connected to a driving voltage line PL configured to transmit the driving voltage ELVDD, a reference voltage line VRL configured to transmit a reference voltage VREF, and an initializing voltage line VIL configured to transmit an initializing voltage Vaint.

The first transistor T1 may be electrically connected between the driving voltage line PL and the light-emitting diode LED. The first transistor T1 may include a gate G1 connected to a first node N1, a first terminal electrically connected to the driving voltage line PL via the fifth transistor T5, and a second terminal connected to a second node N2. The first terminal may be a drain D and the second terminal may be a source S.

The second transistor T2 may be electrically connected between the data line DL and the first node N1. The second transistor T2 may include a gate connected to the scan line GWL, a first terminal connected to the data line DL, and a second terminal connected to the first node N1. The second transistor T2 may be turned on by the scan signal GW transmitted to the scan line GWL to electrically connect the data line DL to the first node N1, and may be configured to transmit a data voltage Vdata received via the data line DL to the first node N1.

The display apparatus 1 of FIG. 1 may operate in a normal mode or a crack detection mode. In the normal mode, the data line DL may be electrically connected to the data driver 20 of FIG. 4, and the data voltage Vdata may be transmitted to the data line DL. The first transistor T1 may receive the data voltage Vdata according to a switching operation of the second transistor T2 and may control the amount of a driving current Id flowing to the light-emitting diode LED.

In the crack detection mode, the data line DL may be electrically connected to the crack detection circuit 400 instead of the data driver 20 of FIG. 4. The crack detection circuit 400 may electrically connect each of the data lines DL to one of the first voltage line VL1, the second voltage line VL2, and the third voltage line VL3. The data voltage Vdata transmitted via the data line DL may be a voltage of any one of the first voltage line VL1, the second voltage line VL2, and the third voltage line VL3. The first transistor T1 may receive a voltage from any one of the first voltage line VL1, the second voltage line VL2, and the third voltage line VL3 according to a switching operation of the second transistor T2 and may control the amount of the driving current Id flowing to the light-emitting diode LED.

The third transistor T3 may be electrically connected between the first node N1 and the reference voltage line VRL. The third transistor T3 may include a gate connected to the reference gate line GRL, a first terminal connected to the first node N1, and a second terminal connected to the reference voltage line VRL. The third transistor T3 may be turned on by the reference signal GR received via the reference gate line GRL and may be configured to transmit the reference voltage VREF received via the reference voltage line VRL to the first node N1.

The power management circuit may be configured to supply a first reference voltage to the reference voltage line VRL in the normal mode, and may be configured to supply a second reference voltage to the reference voltage line VRL in the crack detection mode. For example, in the normal mode, the reference voltage VREF may be the first reference voltage, and, in the crack detection mode, the reference voltage VREF may be a second reference voltage that is greater than the first reference voltage. According to an embodiment, the first reference voltage may be about 0 V to about 2 V, and the second reference voltage may be about 2 V to about 5 V. Therefore, by increasing a charge/discharge difference of the storage capacitor Cst in the crack detection mode, crack detection sensitivity may be increased.

The fourth transistor T4 may be electrically connected between the first transistor T1 and the initializing voltage line VIL. The fourth transistor T4 may include a gate connected to the initialization gate line GBL, a first terminal connected to the second terminal of the sixth transistor T6 and a pixel electrode (e.g., an anode) of the light-emitting diode LED, and a second terminal connected to the initializing voltage line VIL. The fourth transistor T4 may be turned on by the initialization signal GB received via the initialization gate line GBL to transmit the initializing voltage Vaint received via the initializing voltage line VIL to the pixel electrode of the light-emitting diode LED.

According to an embodiment, the initializing voltage Vaint may have a negative value, and may be less than or equal to a detection voltage. An absolute value of the initializing voltage Vaint may be equal to or less than an absolute value of a gate low voltage that turns off an N-type transistor or turns on a P-type transistor. The second node N2 may be supplied with the initializing voltage Vaint by the turned-on sixth transistor T6, and a gate-source voltage of the first transistor T1 may have a value corresponding to a difference between the data voltage Vdata and the initializing voltage Vaint. In the crack detection mode, when the detection voltage having a negative value is supplied as the data voltage Vdata to the data line DL, the gate-source voltage of the first transistor T1 may become 0 V or less, so that the pixel PX may emit black light during a light-emission period. When a crack occurs in a crack detection line and thus a voltage supplied as the data voltage Vdata to the data line DL becomes greater than the detection voltage, the gate-source voltage of the first transistor T1 may exceed 0 V, so that the pixel PX may emit light in a different color other than black during a light-emission period.

The fifth transistor T5 may be electrically connected between the driving voltage line PL and the first transistor T1. The fifth transistor T5 may include a gate connected to the first light-emission control line EML, a first terminal connected to the driving voltage line PL, and a second terminal connected to the first terminal of the first transistor T1. The fifth transistor T5 may be turned on or off according to the first light-emission control signal EM received via the first light-emission control line EML.

The sixth transistor T6 may be connected between the first transistor T1 and the light-emitting diode LED. The sixth transistor T6 may include a gate connected to the second light-emission control line EMBL, a first terminal connected to the second node N2, and a second terminal connected to the light-emitting diode LED. The sixth transistor T6 may be turned on according to the second light-emission control signal EMB received via the second light-emission control line EMBL to electrically connect the second node N2 to the pixel electrode of the light-emitting diode LED.

The storage capacitor Cst may be connected between the first node N1 and the second node N2. For example, the pixel circuit PC according to an embodiment may be a source follower type circuit in which the storage capacitor Cst is connected between the gate of the first transistor T1 and the second terminal (source S) of the first transistor T1. A first storage electrode CEs1 of the storage capacitor Cst may be connected to the first node N1, and a second storage electrode CEs2 thereof may be connected to the second node N2. The storage capacitor Cst may store a voltage corresponding to a threshold voltage of the first transistor T1 and the data voltage Vdata.

According to an embodiment, the hold capacitor Chd may be connected between the driving voltage line PL and the second node N2. A first hold electrode CEh1 of the hold capacitor Chd may be connected to the driving voltage line PL, and a second hold electrode CEh2 thereof may be connected to the second node N2. The hold capacitor Chd may allow a voltage of the second node N2 of the first transistor T1 to have a constant voltage without fluctuating, when a peripheral signal fluctuates.

The light-emitting diode LED may include the pixel electrode connected to the second node N2 and an opposite electrode (e.g., a cathode) on the pixel electrode, and the opposite electrode may receive a common voltage ELVSS. The opposite electrode may be a common electrode that is shared by a plurality of light-emitting diodes LED. The light-emitting diode LED may emit light with a brightness corresponding to the driving current Id.

Although a case where the pixel circuit PC includes six transistors and two capacitors is illustrated in FIGS. 5A and 5B, the disclosure is not necessarily limited thereto. According to an embodiment, the pixel circuit PC may include five transistors and two capacitors. According to an embodiment, the pixel circuit PC may include seven transistors and two capacitors.

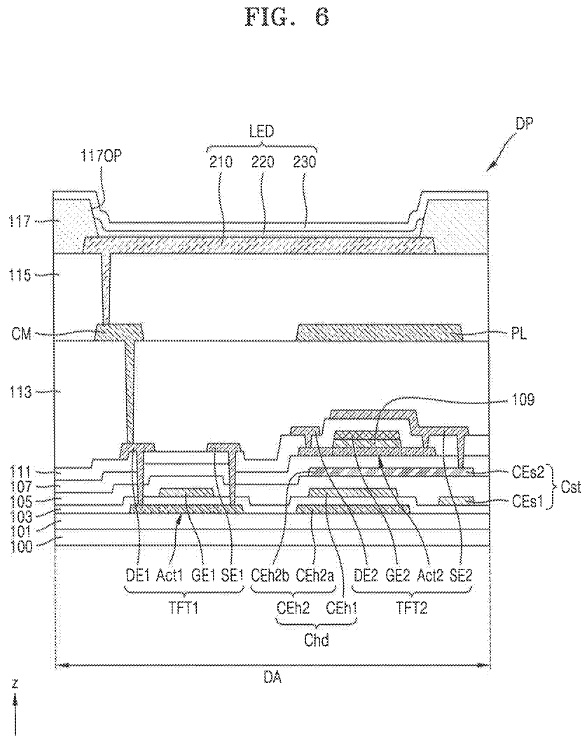

FIG. 6 is a schematic cross-sectional view of a display panel DP according to an embodiment.

Referring to FIG. 6, the display panel DP may include a circuit layer including transistors and capacitors disposed on a substrate 100, and a display element layer disposed on the circuit layer and including a light-emitting diode LED. The circuit layer may include the transistors and the capacitor described above with reference to FIGS. 5A and 5B.

A first thin-film transistor TFT1 illustrated in FIG. 6 corresponds to the sixth transistor T6, and a second thin-film transistor TFT2 corresponds to the first transistor T1. FIG. 6 illustrates a case where the sixth transistor T6 is a silicon thin-film transistor having a polysilicon semiconductor layer, as illustrated in FIG. 5B, and the first transistor T1 is a metal oxide thin-film transistor having a metal oxide semiconductor layer.

A buffer layer 101 may be disposed on the substrate 100. The buffer layer 101 may be an inorganic insulating layer including an inorganic insulating material, such as silicon nitride and/or silicon oxide, and may have a single-layered or multi-layered structure including the aforementioned materials.

The first thin-film transistor TFT1 including a silicon semiconductor layer may be disposed on the buffer layer 101. A first semiconductor layer Act1 disposed on the buffer layer 101 may include polysilicon. The first semiconductor layer Act1 may include a channel region, and impurity regions respectively disposed on both sides of the channel region and doped with impurities. One of the impurity regions may be a source region, and the other may be a drain region.

A sublayer, for example, a second lower hold electrode CEh2a, of the second hold electrode CEh2 of the hold capacitor Chd may be disposed on the buffer layer 101. The second lower hold electrode CEh2a may include polysilicon. The second lower hold electrode CEh2a may include impurity regions doped with impurities.

A first gate insulating layer 103 may be disposed on the first semiconductor layer Act1. The first gate insulating layer 103 may be an inorganic insulating layer including an inorganic insulating material, such as silicon oxide, silicon nitride, and/or silicon oxynitride, and may have a single-layered or multi-layered structure including the aforementioned materials.

A first gate electrode GE1 may be disposed on the first gate insulating layer 103, and may overlap the channel region of the first semiconductor layer Act1. The first storage electrode CEs1 of the storage capacitor Cst and the first hold electrode CEh1 of the hold capacitor Chd may be disposed on the same layer as a layer on which the first gate electrode GE1 is disposed, for example, may be disposed on the first gate insulating layer 103.

The first gate electrode GE1, the first storage electrode CEs1 of the storage capacitor Cst, and the first hold electrode CEh1 of the hold capacitor Chd may include the same materials. The first gate electrode GE1, the first storage electrode CEs1 of the storage capacitor Cst, and the first hold electrode CEh1 of the hold capacitor Chd may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu), and may each be formed as a single layer or multi-layer including the aforementioned materials. According to an embodiment, the first gate electrode GE1, the first storage electrode CEs1 of the storage capacitor Cst, and the first hold electrode CEh1 of the hold capacitor Chd may each be a single layer including molybdenum (Mo).

A second gate insulating layer 105 may be disposed on the first gate electrode GE1, the first storage electrode CEs1 of the storage capacitor Cst, and the first hold electrode CEh1 of the hold capacitor Chd. The second gate insulating layer 105 may be an inorganic insulating layer including an inorganic insulating material, such as silicon oxide, silicon nitride, and/or silicon oxynitride, and may have a single-layered or multi-layered structure including the aforementioned materials.

The second storage electrode CEs2 of the storage capacitor Cst, and a sublayer, for example, a second upper hold electrode CEh2b, of the second hold electrode CEh2 of the hold capacitor Chd may be disposed on the second gate insulating layer 105. The second storage electrode CEs2 of the storage capacitor Cst and the second upper hold electrode CEh2b of the hold capacitor Chd may be integrally connected to each other. The second storage electrode CEs2 of the storage capacitor Cst and the second upper hold electrode CEh2b of the hold capacitor Chd may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu), and may each be formed as a single layer or multi-layer including the aforementioned materials. According to an embodiment, the second storage electrode CEs2 of the storage capacitor Cst, and the second upper hold electrode CEh2b of the hold capacitor Chd may each be a single layer including molybdenum (Mo).

A first interlayer insulating layer 107 may be disposed on the second storage electrode CEs2 of the storage capacitor Cst and the second upper hold electrode CEh2b of the hold capacitor Chd. The first interlayer insulating layer 107 may be an inorganic insulating layer including an inorganic insulating material, such as silicon oxide, silicon nitride, or silicon oxynitride, and may have a single-layered or multi-layered structure including the aforementioned materials. According to an embodiment, the first interlayer insulating layer 107 may have a stack structure of a layer including silicon oxide and a layer including silicon nitride.

The second thin-film transistor TFT2 including a metal oxide semiconductor layer may be disposed on the first interlayer insulating layer 107. A second semiconductor layer Act2 disposed on the first interlayer insulating layer 107 may include a metal oxide semiconductor, and the metal oxide semiconductor may include at least one element selected from the group consisting of indium (In), gallium (Ga), tin (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn). For example, the metal oxide semiconductor may include InSnZnO (ITZO) or InGaZnO (IGZO). The second semiconductor layer Act2 may include a channel region, and impurity regions respectively disposed on both sides of the channel region and doped with impurities. One of the impurity regions may be a source region, and the other may be a drain region.

The second semiconductor layer Act2 may be disposed on a different layer from a layer on which the first semiconductor layer Act1 is disposed. A vertical distance from an upper surface of the substrate 100 to the second semiconductor layer Act2 may be greater than a vertical distance from the upper surface of the substrate 100 to the first semiconductor layer Act1.

A third gate insulating layer 109 may be disposed on the second semiconductor layer Act2. The third gate insulating layer 109 may be an inorganic insulating layer including an inorganic insulating material, such as silicon oxide, silicon nitride, or silicon oxynitride, and may have a single-layered or multi-layered structure including the aforementioned materials.

FIG. 6 illustrates that the third gate insulating layer 109 has substantially the same pattern and/or width as a second gate electrode GE2, which will be described later, but the disclosure is not necessarily limited thereto. According to an embodiment, the third gate insulating layer 109 may cover an upper surface of the second semiconductor layer Act2 and an upper surface of the first interlayer insulating layer 107.

The second gate electrode GE2 may be disposed on the third gate insulating layer 109. The second gate electrode GE2 may overlap the channel region of the second semiconductor layer Act2. The second gate electrode GE2 may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu), and may be formed as a single layer or multi-layer including the aforementioned materials. According to an embodiment, the second gate electrode GE2 may have a three-layered structure of Ti layer/Al layer/Ti layer.

A second interlayer insulating layer 111 may be disposed on the second gate electrode GE2. The second interlayer insulating layer 111 may be an inorganic insulating layer including an inorganic insulating material, such as silicon oxide, silicon nitride, or silicon oxynitride, and may have a single-layered or multi-layered structure including the aforementioned materials. According to an embodiment, the second interlayer insulating layer 111 may have a stack structure of a layer including silicon oxide and a layer including silicon nitride.

A first source electrode SE1, a first drain electrode DE1, a second source electrode SE2, and a second drain electrode DE2 may be disposed on the same layer, for example, the second interlayer insulating layer 111. The first source electrode SE1 may be connected to the source region of the first semiconductor layer Act1, and the first drain electrode DE1 may be connected to the drain region of the first semiconductor layer Act1. The second source electrode SE2 may be connected to the source region of the second semiconductor layer Act2, the second storage electrode CEs2 of the storage capacitor Cst, and the second upper hold electrode CEh2b of the hold capacitor Chd. The second drain electrode DE2 may be connected to the drain region of the second semiconductor layer Act2.

The first source electrode SE1, the first drain electrode DE1, the second source electrode SE2, and the second drain electrode DE2 may include the same materials. The first source electrode SE1, the first drain electrode DE1, the second source electrode SE2, and the second drain electrode DE2 may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu), and may each be formed as a single layer or multi-layer including the aforementioned materials. According to an embodiment, each of the first source electrode SE1, the first drain electrode DE1, the second source electrode SE2, and the second drain electrode DE2 may have a multi-layer structure of Ti layer/Al layer/Ti layer.

A first organic insulating layer 113 may be disposed on the first source electrode SE1, the first drain electrode DE1, the second source electrode SE2, and the second drain electrode DE2. The first organic insulating layer 113 may include an organic insulating material, such as acryl, benzocyclobutene (BCB), polyimide, or hexamethyldisiloxane (HMDSO).

A contact electrode CM and the driving voltage line PL may be disposed on the first organic insulating layer 113. The contact electrode CM and the driving voltage line PL may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and and/or copper (Cu), and may each be formed as a single layer or multi-layer including the aforementioned materials. According to an embodiment, each of the contact electrode CM and the driving voltage line PL may have a three-layered structure of Ti layer/Al layer/Ti layer.

A second organic insulating layer 115 may be disposed on the contact electrode CM and the driving voltage line PL. The second organic insulating layer 115 may include an organic insulating material, such as acryl, benzocyclobutene (BCB), polyimide, or hexamethyldisiloxane (HMDSO).

The light-emitting diode LED may be disposed on the second organic insulating layer 115. The light-emitting diode LED may include a pixel electrode 210, an intermediate layer 220, and an opposite electrode 230.

The pixel electrode 210 may be disposed on the second organic insulating layer 115. The pixel electrode 210 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or a compound or mixture of these materials. The pixel electrode 210 may include a reflective layer including the aforementioned material, and a transparent conductive layer disposed above or/and below the reflective layer. The transparent conductive layer may include, for example, indium tin oxide (ITO), indium zinc oxide (IZO), zinc oxide (ZnO), indium oxide (In₂O₃), indium gallium oxide (IGO), or aluminum zinc oxide (AZO). According to an embodiment, the pixel electrode 210 may have a three-layered structure of ITO/Ag/ITO layers that are sequentially stacked.

A bank layer 117 may cover an edge portion of the pixel electrode 210, and may expose a center portion of the pixel electrode 210 via an opening 117OP of the bank layer 117. The bank layer 117 may include an organic insulating material, such as acryl, benzocyclobutene (BCB), polyimide, or hexamethyldisiloxane (HMDSO). According to an embodiment, the bank layer 117 may be formed in black. The bank layer 117 may include a light shielding material, and may be provided in a black color. The light shielding material may include carbon black, carbon nanotubes, resin or paste including a black pigment, metal particles (e.g., nickel (Ni), aluminum (Al), molybdenum (Mo), and an alloy thereof), metal oxide particles (e.g., a chromium oxide), or metal nitride particles (e.g., a chromium nitride). When the bank layer 117 includes the light shielding material, external light reflection due to metal structures disposed under the bank layer 117 may be reduced. The opening 117OP of the bank layer 117 may define a light-emission area of the light-emitting diode LED.

The intermediate layer 220 may include an emission layer. According to some embodiments, the intermediate layer 220 may further include a functional layer interposed between the pixel electrode 210 and the emission layer and/or between the emission layer and the opposite electrode 230. The functional layer may include a hole transport layer (HTL), a hole injection layer (HIL), an electron transport layer (ETL), and/or an electron injection layer (EIL). According to some embodiments, the intermediate layer 220 may include a first stack including an emission layer and a functional layer, a second stack including an emission layer and a functional layer, and a charge generation layer between the first stack and the second stack. The charge generation layer may include a negative charge generation layer and a positive charge generation layer. The luminous efficiency of a tandem light-emitting diode (LED) including a plurality of emission layers may be further increased by the negative charge generation layer and the positive charge generation layer.

The negative charge generation layer may be an n-type charge generation layer. The negative charge generation layer may supply electrons. The negative charge generation layer may include a host and a dopant. The host may include an organic material. The dopant may include a metal material. The positive charge generation layer may be a p-type charge generation layer. The positive charge generation layer may supply holes. The positive charge generation layer may include a host and a dopant. The host may include an organic material. The dopant may include a metal material.

The opposite electrode 230 may include a conductive material having a low work function. The opposite electrode 230 may include a transparent or semitransparent layer including, for example, silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca) or an alloy of these materials. As used herein, the phrase “low work function” may mean a work function that is equal to or less than that of any of the above-listed materials that the opposite electrode 230 may include. Alternatively, the opposite electrode 230 may further include a layer, such as indium tin oxide, indium zinc oxide, zinc oxide, or indium oxide, on the (semi)transparent layer including any of the above-described materials.

According to an embodiment, a capping layer may be disposed on the opposite electrode 230. The capping layer may increase light extraction efficiency of the light-emitting diode LED. The capping layer may include lithium fluoride (LiF), an inorganic material, or/and an organic material.

FIG. 6 illustrates a case where the first thin-film transistor TFT1 is a silicon thin-film transistor and the second thin-film transistor TFT2 is a metal oxide thin-film transistor, but the disclosure is not necessarily limited thereto. As described above, both the first thin-film transistor TFT1 and the second thin-film transistor TFT2 may be metal oxide thin-film transistors.

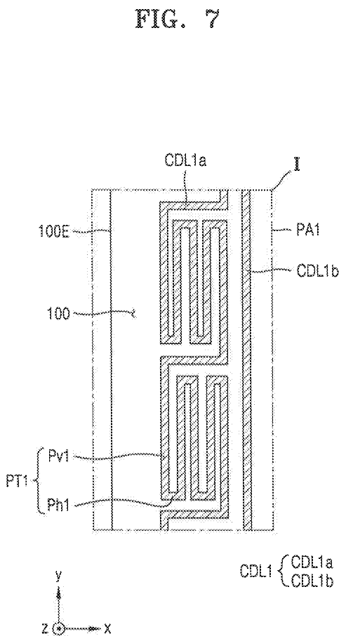

FIG. 7 is a schematic plan view of a region I of the display panel DP of FIG. 4.

Referring to FIG. 7, the first crack detection line CDL1 may include the first subline CDL1a and the second subline CDL1b. The first crack detection line CDL1 may be disposed in the first peripheral area PA1, and may extend along an edge 100E of the substrate 100. The first subline CDL1a may be disposed adjacent to the edge 100E of the substrate 100, and the second subline CDL1b may be disposed between the first subline CDL1a and the display area DA of FIG. 4. As described above with reference to FIG. 4, the first subline CDL1a and the second subline CDL1b may be electrically connected to each other at the center of the upper (+y direction) side of the substrate 100. Each of the first subline CDL1a and the second subline CDL1b may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and and/or copper (Cu), and may be formed as a single layer or multi-layer including the aforementioned materials.

The first subline CDL1a or the second subline CDL1b may include a plurality of first serpentine (e.g., zigzag) patterns PT1 connected in series with each other. With regard to this, FIG. 7 illustrates that the first subline CDL1a includes first serpentine patterns PT1. The first serpentine patterns PT1 may be disposed adjacent to an edge 100E of the substrate 100 and parallel to the edge 100E, and ends of neighboring first serpentine patterns PT1 may be connected to each other.

Each of the first serpentine patterns PT1 may include first vertical portions Pv1 each extending in a direction parallel to the edge 100E of the substrate 100 and spaced apart from each other in a direction perpendicular to the edge 100E, and first horizontal portions Ph1 connecting neighboring first vertical portions Pv1 to each other. The first horizontal portions Ph1 may be alternately disposed on respective one sides (e.g., in the +y direction) and other respective sides (e.g., in the -y direction) of the first vertical portions Pv1. The first serpentine pattern PT1 may have a meandering shape in a direction parallel to the edge 100E of the substrate 100.

According to the shapes of the first serpentine patterns PT1, a resistance value of the first crack detection line CDL1 may be set (or designed) to a desired value. According to an embodiment, the first subline CDL1a and the second subline CDL1b might not include the serpentine patterns, and may each have a linear shape extending parallel to the edge 100E of the substrate 100.

When a crack occurs in an area where the first crack detection line CDL1 is disposed, the first crack detection line CDL1 may be short-circuited, or may be damaged to thereby increase wiring resistance. As described above with reference to FIG. 4, the first subline CDL1a of the first crack detection line CDL1 may receive a detection voltage via the first connection line CL1, and the second subline CDL1b thereof may be electrically connected to the second voltage line VL2. According to the short circuit or the increase in the wiring resistance of the first crack detection line CDL1, a voltage of the second voltage line VL2 may have a level that is higher than the detection voltage.

Although FIG. 7 has been described based on the first crack detection line CDL1, the second crack detection line CDL2 of FIG. 4 may also have the same or similar shape as or to the first crack detection line CDL1. For example, the second crack detection line CDL2 may have a shape that is linearly symmetrical with the first crack detection line CDL1 with respect to the imaginary line IML of FIG. 4 passing through the center of the display panel DP of FIG. 4.

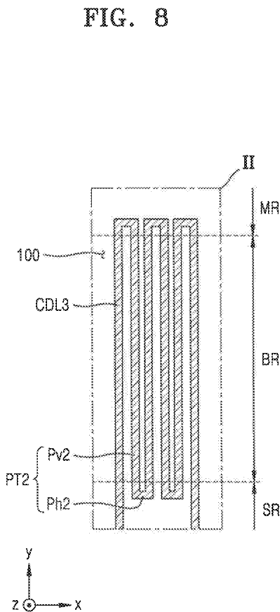

FIG. 8 is a schematic plan view of a region II of the display panel DP of FIG. 4.

Referring to FIG. 8, the third crack detection line CDL3 may extend from the subregion SR of the substrate 100 to the main region MR thereof via the bending region BR thereof and then extend over the bending region BR to the subregion SR. As shown in FIG. 4, the third crack detection line CDL3 may be disposed adjacent to an edge of the substrate 100 in the bending region BR. The third crack detection line CDL3 may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu), and may be formed as a single layer or multi-layer including the aforementioned materials.

According to an embodiment, the third crack detection line CDL3 may include a second serpentine pattern PT2. The second serpentine pattern PT2 may extend along a direction crossing the bending region BR, for example, the second direction (y direction), and may include second vertical portions Pv2 spaced apart from each other in the first direction (x direction), and second horizontal portions Ph2 connecting neighboring second vertical portions Pv2 to each other. The second horizontal sections Ph2 may be disposed alternately on the side of the main region MR and the side of the subregion SR. The second serpentine pattern PT2 may have a meandering shape in a direction parallel to the edge of the substrate 100.

According to the shape of the second serpentine pattern PT2, a resistance value of the third crack detection line CDL3 may be set (or designed) to a desired value. According to an embodiment, the third crack detection line CDL3 might not include a serpentine pattern, and may have a curved shape that extends from the subregion SR to the main region MR via the bending region BR and then extends over the bending region BR to the subregion SR.

When a crack occurs in an area where the third crack detection line CDL3 is disposed, the third crack detection line CDL3 may be short-circuited, or may be damaged to thereby increase wiring resistance. As described above with reference to FIG. 4, a first end of the third crack detection line CDL3 may be electrically connected to the pad portion PAD through the thirdconnection line CL3 so as to receive a detection voltage from the power management circuit. A second end of the third crack detection line CDL3 may be electrically connected to the third voltage line VL3. According to the short circuit or the increase in the wiring resistance of the third crack detection line CDL3, a voltage of the third voltage line VL3 may have a level that is higher than the detection voltage.

Although FIG. 8 has been described based on the third crack detection line CDL3, the fourth crack detection line CDL4 of FIG. 4 may also have the same or similar shape as or to the third crack detection line CDL3. For example, the fourth crack detection line CDL4 may have a shape that is linearly symmetrical with the third crack detection line CDL3 with respect to the imaginary line IML of FIG. 4 passing through the center of the display panel DP of FIG. 4.

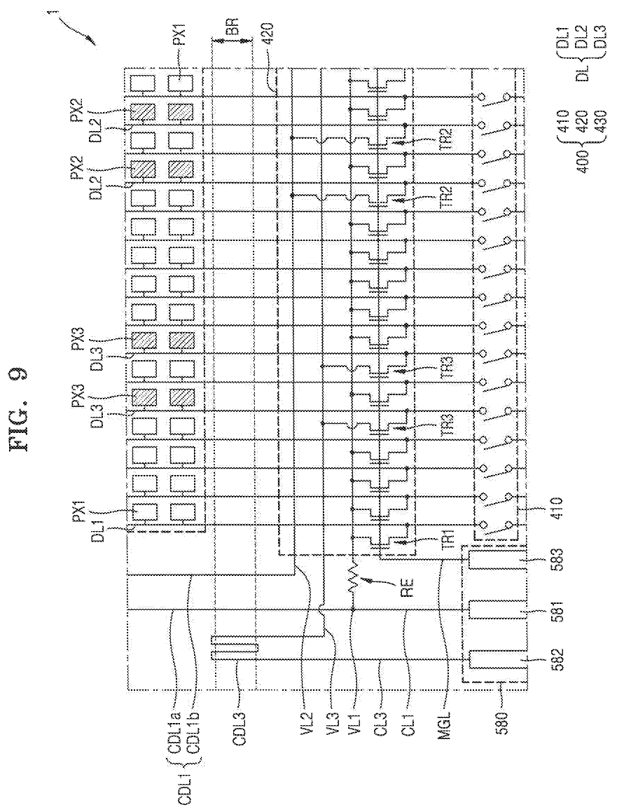

FIG. 9 is a schematic view of the display apparatus 1 according to an embodiment.

Referring to FIG. 9, the display apparatus 1 may include the plurality of pixels, the data lines DL, the first crack detection line CDL1, the third crack detection line CDL3, the crack detection circuit 400, and a power management circuit 580. For convenience of illustration, FIG. 9 illustrates that the power management circuit 580 is electrically connected to the first connection line CL1, the third connection line CL3, and a gate signal line MGL. However, the disclosure is not necessarily limited thereto. The power management circuit 580 may be disposed on the display circuit board 30, as described above with reference to FIG. 4, and may be electrically connected to the first connection line CL1, the third connection line CL3, and the gate signal line MGL through the pad portion 30P of the display circuit board 30 and the pad portion PAD of the display panel DP.

The data lines DL may include first data lines DL1 electrically connected to first detection transistors TR1, second data lines DL2 electrically connected to second detection transistors TR2, and third data lines DL3 electrically connected to third detection transistors TR3. Each of the second data line DL2 and the third data line DL3 may be disposed between adjacent first data lines DL1. The number of first data lines DL1 may be greater than the number of second data lines DL2 and the number of third data lines DL3. For example, FIG. 9 illustrates two second data lines DL2 and two third data lines DL3 disposed between twelve first data lines DL1. However, the disclosure is not necessarily limited thereto. The number of data lines DL may be designed in various ways.

The plurality of pixels may be disposed in the display area DA of FIG. 4, and each of the plurality of pixels may include the pixel circuit PC of FIGS. 5A and 5B and the light-emitting diode LED of FIGS. 5A and 5B electrically connected to the pixel circuit PC. The pixel circuit PC of each of the plurality of pixels may be electrically connected to a corresponding data line among the data lines DL. Hereinafter, pixels electrically connected to the first data line DL1 are represented as first pixels PX1, pixels electrically connected to the second data line DL2 are represented as second pixels PX2, and pixels electrically connected to the third data line DL3 are represented as third pixels PX3.

The first crack detection line CDL1 may be disposed outside the display area DA, and may extend along a portion of an edge of the substrate 100 of FIG. 4. The first crack detection line CDL1 may include a first subline CDL1a and a second subline CDL1b. The first subline CDL1a may be electrically connected to the first connection line CL1, and the second subline CDL1b may be electrically connected to the second voltage line VL2.

The first connection line CL1 may be electrically connected to a first output terminal 581 of the power management circuit 580. The power management circuit 580 may be configured to supply a detection voltage having a negative value to the first connection line CL1. According to an embodiment, the detection voltage may be a gate low voltage. According to an embodiment, the power management circuit 580 may be configured to supply a ground voltage as the detection voltage to the first connection line CL1. For example, the first connection line CL1 may be grounded.

The first connection line CL1 may be electrically connected to the first voltage line VL1. A resistance element RE having a resistance corresponding to the resistance of the first crack detection line CDL1 may be disposed between the first connection line CL1 and the first voltage line VL1. The detection voltage may be supplied to the first voltage line VL1 via the first connection line CL1. The detection voltage may be supplied to the second voltage line VL2 via the first crack detection line CDL1. When a crack or the like occurs in the first crack detection line CDL1, a voltage of the second voltage line VL2 may become different from the detection voltage. For example, a voltage level of the second voltage line VL2 may be higher than a voltage level of the first voltage line VL1.

The third crack detection line CDL3 may traverse the bending region BR, and a first end of the third crack detection line CDL3 may be electrically connected to the third connection line CL3 and a second end of the third crack detection line CDL3 may be electrically connected to the third voltage line VL3. The third connection line CL3 may be electrically connected to a second output terminal 582 of the power management circuit 580. The power management circuit 580 may be configured to supply a detection voltage having a negative value to the third connection line CL3. According to an embodiment, the power management circuit 580 may be configured to supply a ground voltage as the detection voltage to the third connection line CL3. For example, the third connection line CL3 may be grounded. The detection voltage may be supplied to the third voltage line VL3 via the third crack detection line CDL3. When a crack or the like occurs in the third crack detection line CDL3, a voltage of the third voltage line VL3 may become different from the detection voltage. For example, a voltage level of the third voltage line VL3 may be higher than the voltage level of the first voltage line VL1.

The crack detection circuit 400 may include a switch circuit 410, a connection circuit 420 and the gate signal line MGL. The switch circuit 410 may electrically connect or disconnect the data lines DL to or from the data driver 20 of FIG. 4 according to a detection control signal applied from a processor. The connection circuit 420 may electrically connect the data lines DL to a corresponding voltage line according to a detection gate signal supplied to the gate signal line MGL.

The connection circuit 420 may include first detection transistors TR1 connected between the first data lines DL1 and the first voltage line VL1, second detection transistors TR2 connected between the second data lines DL2 and the second voltage line VL2, and third detection transistors TR3 connected between the third data lines DL3 and the third voltage line VL3. A gate (or a gate electrode) of each of the first detection transistors TR1, the second detection transistors TR2, and the third detection transistors TR3 may be electrically connected to the gate signal line MGL.

The gate signal line MGL may be electrically connected to a third output terminal 583 of the power management circuit 580, and may receive a detection gate signal from the power management circuit 580. According to an embodiment, the gate signal line MGL may receive a detection gate signal from a controller or an external device. The detection gate signal may be a square wave signal in which a voltage of a gate-on level for turning on the first, second, and third detection transistors TR1, TR2, and TR3 and a voltage of a gate-off level for turning off the first, second, and third detection transistors TR1, TR2, and TR3 are alternately supplied. According to an embodiment, as illustrated in FIG. 9, the first, second, and third detection transistors TR1, TR2, and TR3 may be n-type transistors. In this case, the voltage of the gate-on level may be a gate high voltage, and the voltage of the gate-off level may be a gate low voltage. According to an embodiment, the first, second, and third detection transistors TR1, TR2, and TR3 may be p-type transistors. In this case, the voltage of the gate-on level may be a gate low voltage, and the voltage of the gate-off level may be a gate high voltage.

The display apparatus 1 may operate in a normal mode or a crack detection mode. In the normal mode, the switch circuit 410 may electrically connect the data lines DL to the data driver 20 so that each of the data lines DL may receive a corresponding data voltage from the data driver 20. The pixels may emit light with a brightness corresponding to the received data voltage.

In the crack detection mode, the switch circuit 410 may electrically separate the data lines DL from the data driver 20 according to the detection control signal. The first data line DL1 may be electrically connected to the first voltage line VL1 by the first detection transistor TR1 turned on according to the detection gate signal. The second data line DL2 may be electrically connected to the second voltage line VL2 by the second detection transistor TR2 turned on according to the detection gate signal. The third data line DL3 may be electrically connected to the third voltage line VL3 by the third detection transistor TR3 turned on according to the detection gate signal.

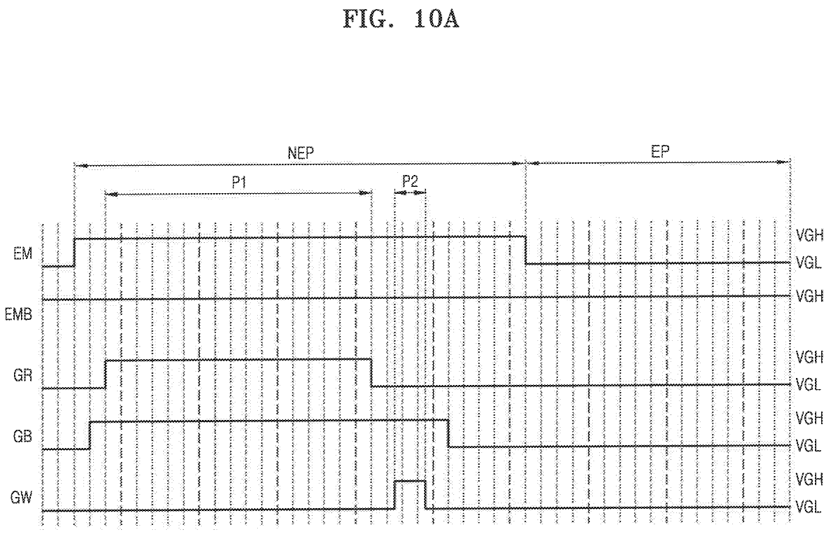

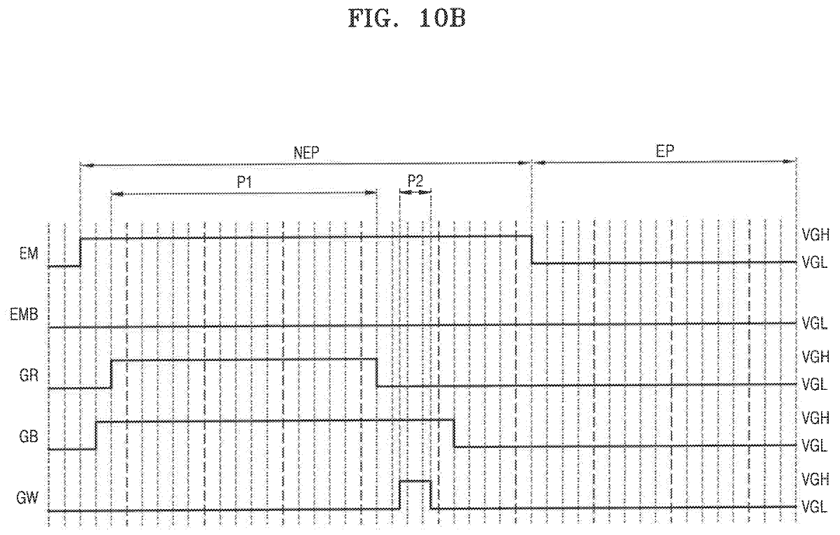

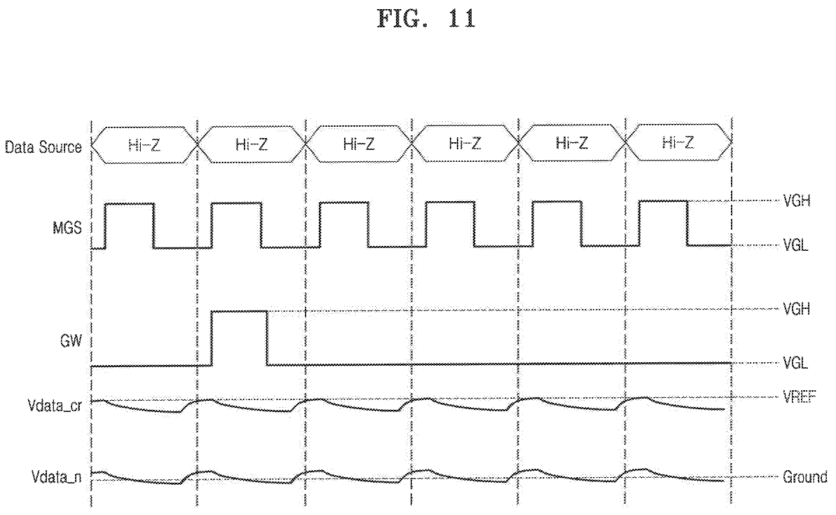

FIGS. 10A and 10B are schematic signal diagrams for explaining an operation of a pixel circuit PC according to an embodiment. FIG. 11 is a schematic signal diagram for explaining an operation of a crack detection circuit 400 according to an embodiment.

FIGS. 10A and 10B schematically illustrate signals applied to the pixel circuit PC of FIGS. 5A and 5B when the display apparatus 1 of FIG. 1 operates in the crack detection mode. As illustrated in FIG. 5A, FIG. 10A illustrates a case where the fifth transistor T5 is a P-type transistor and the first, second, third, fourth, and sixth transistors T1, T2, T3, T4, and T6 are N-type transistors. As illustrated in FIG. 5B, FIG. 10B illustrates a case where the fifth transistor T5 and the sixth transistor T6 may be P-type transistors and the first, second, third, and fourth transistors T1, T2, T3, and T4 are N-type transistors.

Referring to FIGS. 5A, 5B, 10A, 10B, and 11 together, each of the scan signal GW, the reference signal GR, the initialization signal GB, the first light-emission control signal EM, and the second light-emission control signal EMB may have a high-level voltage (gate high voltage VGH) during some periods and a low-level voltage (gate low voltage VGL) during some periods. The gate high voltage VGH may turn on N-type transistors and turn off P-type transistors. The gate low voltage VGL may turn off N-type transistors and turn on P-type transistors. According to an embodiment, the gate high voltage VGH may be about 5 V to about 14 V, and the gate low voltage VGL may be about -10 V to about -1 V.

In the crack detection mode, the data line DL may be electrically separated from the data driver 20 of FIG. 4 by the crack detection circuit 400 of FIG. 4. For example, a data source connected to a data driver 20 may be in a high impedance (Hi-Z) state. The data line DL may be connected to any one of the first detection transistor TR1, the second detection transistor TR2, and the third detection transistor TR3 of the connection circuit 420 of FIG. 9. Respective gates of the first detection transistor TR1, the second detection transistor TR2, and the third detection transistor TR3 may be electrically connected to the gate signal line MGL of FIG. 9, and a detection gate signal MGS may be supplied to the gate signal line MGL. The detection gate signal MGS may be a square wave in which the gate low voltage VGL and the gate high voltage VGH alternate with each other.

The first detection transistor TR1, the second detection transistor TR2, and the third detection transistor TR3 may be N-type transistors or P-type transistors. When the first detection transistor TR1, the second detection transistor TR2, and the third detection transistor TR3 are N-type transistors, the gate-on voltage may be the gate high voltage VGH, and the gate-off voltage may be the gate low voltage VGL. When the first detection transistor TR1, the second detection transistor TR2, and the third detection transistor TR3 are P-type transistors, the gate-on voltage may be the gate low voltage VGL, and the gate-off voltage may be the gate high voltage VGH. A case where the first detection transistor TR1, the second detection transistor TR2, and the third detection transistor TR3 are N-type transistors will now be focused on and described.

A pixel PX may operate in a non-emission period NEP during which the data voltage Vdata is input, and an emission period EP during which the light-emitting diode LED emits light. The non-emission period NEP may include a first period P1 and a second period P2.

In the crack detection mode, a first light-emission control signal EM of the gate high voltage VGH may be supplied (applied) to the first light-emission control line EML during a non-emission period NEP, and a first light-emission control signal EM of the gate low voltage VGL may be supplied to the first light- emission control line EML during an emission period EP. Therefore, the fifth transistor T5 may be turned off during the non-emission period NEP, and the fifth transistor T5 may be turned on during the emission period EP.

As illustrated in FIG. 5A and FIG. 10A, when the sixth transistor T6 is an N-type transistor, a second light-emission control signal EMB of the gate high voltage VGH may be supplied to the second light-emission control line EMBL during the non-emission period NEP and the emission period EP. As illustrated in FIG. 5B and FIG. 10B, when the sixth transistor T6 is a P-type transistor, a second light-emission control signal EMB of the gate low voltage VGL may be supplied to the second light-emission control line EMBL during the non-emission period NEP and the emission period EP. For example, the sixth transistor T6 may be turned on during the non-emission period NEP and the emission period EP.

The first period P1 may be an initialization period for initializing the first node N1 to which the gate G1of the first transistor T1 is connected, the second node N2 to which the second terminal (or the source S) of the first transistor T1 is connected, and the pixel electrode of the light-emitting diode LED. In the first period P1, a reference signal GR of the gate high voltage VGH may be supplied to the reference gate line GRL, an initialization signal GB of the gate high voltage VGH may be supplied to the initialization gate line GBL, and a scan signal GW of the gate low voltage VGL may be supplied to the scan line GWL.

The third transistor T3 may be turned on by the reference signal GR, and the reference voltage VREF may be supplied from the reference voltage line VRL to the first node N1. The fourth transistor T4 may be turned on by the initialization signal GB, and the initializing voltage Vaint may be supplied from the initializing voltage line VIL to the pixel electrode of the light-emitting diode LED. At this time, because the sixth transistor T6 is turned on, the initializing voltage Vaint may be supplied to the second node N2, and a charge corresponding to a difference between the reference voltage VREF and the initializing voltage Vaint may be stored in the storage capacitor Cst.

According to an embodiment, in the normal mode, a first light-emission control signal EM of the gate low voltage VGL may be supplied so as to partially overlap the reference signal GR, and thus the fifth transistor T5 may be turned on. Accordingly, the reference voltage VREF may be supplied to the first node N1 and a driving voltage ELVDD may be supplied to the first terminal (or the drain D) of the first transistor T1, and thus the first transistor T1 may be turned on. A voltage of the second node N2 may drop below a difference between the reference voltage VREF and a threshold voltage of the first transistor T1, and the first transistor T1 may be turned off. A charge corresponding to the threshold voltage of the first transistor T1 may be stored in the storage capacitor Cst, and thus the threshold voltage of the first transistor T1 may be compensated for.

In the crack detection mode, a first light-emission control signal EM of the gate high voltage VGH may be supplied to the first light- emission control line EML during the non-emission period NEP, and thus the fifth transistor T5 may be kept in a turned-off state. Accordingly, the voltage of the first node N1 may be maintained at the reference voltage VREF during the first period P1, and a charge corresponding to a difference between the reference voltage VREF and the initializing voltage Vaint may be stored in the storage capacitor Cst.

The second period P2 may be a write period in which the data voltage Vdata is supplied to the pixel PX. In the second period P2, a scan signal GW of the gate high voltage VGH may be supplied to the scan line GWL, and an initialization signal GB of the gate high voltage VGH may be supplied to the initialization gate line GBL. A reference signal GR of the gate low voltage VGL may be supplied to the reference gate line GRL. A period during which the scan signal GW is at the gate high voltage VGH may overlap with a period during which the detection gate signal MGS is at the gate high voltage VGH.

The second transistor T2 may be turned on by the scan signal GW, and the turned-on second transistor T2 may transmit the data voltage Vdata from the data line DL to the first node N1, i.e., to the gate G1 of the first transistor T1. Accordingly, the voltage of the first node N1 may be changed from the reference voltage VREF to a voltage corresponding to the data voltageVdata. The fourth transistor T4 may be turned on by the initialization signal GB, and the sixth transistor T6 may be turned on by the second light-emission control signal EMB, so that the initializing voltage Vaint may be supplied to the second node N2. According to the detection gate signal MGS, the first detection transistor TR1, the second detection transistor TR2, and the third detection transistor TR3 may be turned on, so that the data line DL may be electrically connected to a corresponding voltage line among the first voltage line VL1, the second voltage line VL2, and the third voltage line VL3.

When the data line DL is electrically connected to the first voltage line VL1 through the first detection transistor TR1, the data voltage Vdata may be a detection voltage. The detection voltage may be either the gate low voltage VGL or a ground voltage Ground. In this regard, FIG. 11 illustrates a case where the detection voltage is the ground voltage Ground. A pixel PX electrically connected to the first voltage line VL1 may be supplied with a normal voltage Vdata_n adjacent to the ground voltage Ground as the data voltage Vdata. The first node N1 may have a negative voltage value, and the gate-source voltage of the first transistor T1 may be less than or equal to 0 V, which is a difference between the voltage of the first node N1 and the initializing voltage Vaint.

When the data line DL is electrically connected to the second voltage line VL2 through the second detection transistor TR2 and there is no crack in the first crack detection line CDL1 of FIG. 4 and the second crack detection line CDL2 of FIG. 4, the data voltage Vdata may be the normal voltage Vdata_n. The first node N1 may be discharged and thus have a negative voltage value, and the gate-source voltage of the first transistor T1 may be less than or equal to 0 V.

When the data line DL is electrically connected to the second voltage line VL2 through the second detection transistor TR2 and crack occurs in the first crack detection line CDL1 or the second crack detection line CDL2, the data voltage Vdata may have a higher level than the detection voltage. For example, the data voltage Vdata may be a crack voltage Vdata_cr close to the reference voltage VREF. Therefore, the storage capacitor Cst might not be sufficiently discharged, and the first node N1 may have a positive voltage value. Thus, the gate-source voltage of the first transistor T1 may be greater than 0 V.

Similarly, when the data line DL is electrically connected to the third voltage line VL3 through the third detection transistor TR3 and there is no crack in the third crack detection line CDL3 of FIG. 4 and the fourth crack detection line CDL4 of FIG. 4, the data voltage Vdata may be the normal voltage Vdata_n. The gate-source voltage of the first transistor T1 may be 0 V or less.

When the data line DL is electrically connected to the third voltage line VL3 through the third detection transistor TR3 and crack occurs in the third crack detection line CDL3 or the fourth crack detection line CDL4, the data voltage Vdata may be a higher crack voltage Vdata_cr than the detection voltage. The gate-source voltage of the first transistor T1 may be greater than 0 V.

The light-emitting diode LED may emit light during the emission period EP. During the emission period EP, the first light-emission control signal EM of the gate low voltage VGL may be supplied to the first light-emission control line EML. The scan signal GW, the reference signal GR, and the initialization signal GB may have gate low voltages VGL.

During the emission period EP, the fifth transistor T5 may be turned on by the first light-emission control signal EM, and the driving voltage ELVDD may be supplied to the first terminal of the first transistor T1 via the turned-on fifth transistor T5. A driving current Id corresponding to the gate-source voltage of the first transistor T1 may be output, and the driving current Id may flow to the light-emitting diode LED through the sixth transistor T6 turned on by the second light-emission control signal EMB. The light-emitting diode LED may emit light with a brightness corresponding to a magnitude of the driving current Id.

When the gate-source voltage of the first transistor T1 is 0 V or less, the light-emitting diode LED may emit light in black. When the gate-source voltage of the first transistor T1 is greater than 0 V, the magnitude of the driving current Id becomes relatively large, so that the light-emitting diode LED may emit light in a color other than black. For example, when a crack occurs in the first crack detection line CDL1 and thus the voltage of the first node N1 is the crack voltage Vdata_cr, pixels PX electrically connected to the second voltage line VL2 may emit light in a color other than black. Therefore, a bright line with higher brightness than neighboring pixels PX emitting black light may be displayed, thereby confirming the occurrence of a crack.

According to an embodiment, the power management circuit 580 of FIG. 9 may be configured to supply a first reference voltage to the reference voltage line VRL in the normal mode and supply a second reference voltage to the reference voltage line VRL in the crack detection mode. A level of the second reference voltage may be higher than a level of the first reference voltage. For example, the first reference voltage may be about 0 V to about 2 V, and the second reference voltage may be about 2 V to about 5 V. By setting the level of the second reference voltage to be higher than the level of the second first voltage, crack detection sensitivity may be improved.

According to an embodiment, the power management circuit 580 may be configured to supply a first initializing voltage to the initializing voltage line VIL in the normal mode and supply a second initializing voltage to the initializing voltage line VIL in the crack detection mode. A level of the second initializing voltage may be lower than a level of the first initializing voltage. For example, the second initializing voltage may be equal to or lower than the gate low voltage VGL. According to an embodiment, the first initializing voltage may be about -2 V to about 0 V, and the second initializing voltage may be about -10 V to about -2 V.

According to an embodiment, when the detection voltage is the gate low voltage VGL, the low level voltage of the detection gate signal MGS may be set to be lower than the gate low voltage VGL. When the low level voltage of the detection gate signal MGS is equal to or higher than the gate low voltage VGL, the first detection transistor TR1, the second detection transistor TR2, and the third detection transistor TR3 might not be turned on.

Embodiments of the disclosure may effectively detect whether the display panel DP is defective, by using a voltage having a negative value as the detection voltage or by using a ground voltage as the detection voltage.

Display apparatuses 1 as described herein, according to embodiments, may be utilized in various electronic devices. An electronic device, according to an embodiment, may include the above-described display apparatus 1, and may further include a module or device having other additional functions in addition to the display apparatus 1.

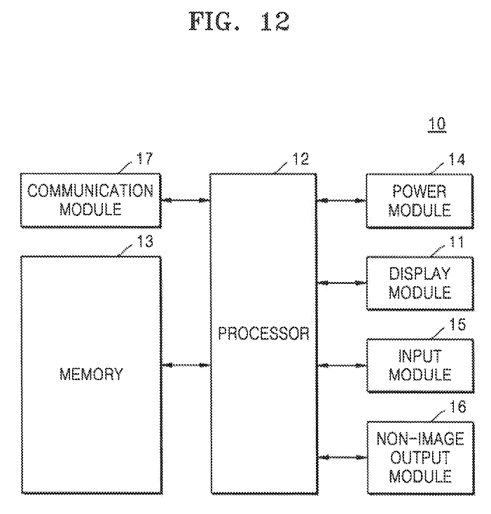

FIG. 12 is a schematic block diagram of an electronic device 10 according to an embodiment.

Referring to FIG. 12, the electronic device 10, according to an embodiment, may include a display module 11, a processor 12, a memory 13, and a power module 14. The electronic device 10 may further include an input module 15, a non-image output module16, and/or a communication module 17.

The electronic device 10 may output various information in the form of an image through the display module 11. When the processor 12 executes an application stored in the memory 13, image information that is provided by an application may be provided to a user through the display module 11. The power module 14 may include a power supply module, such as a power adapter or a battery device, and a power conversion module that converts power supplied by the power supply module to generate power necessary for an operation of the electronic device 10. The input module 15 may provide input information to the processor 12 and/or the display module 11. The non-image output module 16 may receive information other than an image, for example, sound, haptics, light-emission, received from the processor 12, and may provide the information to the user. The communication module 17, which is a module responsible for transmitting and receiving information between the electronic device 10 and an external device, may include a reception unit and a transmission unit.

According to an embodiment, the processor 12 may be provided as two or more processors divided by functional or structural aspects. For example, the processor 12 may include a main processor in the form of a first drive chip including a CPU, and an auxiliary processor in the form of a second drive chip including a controller that receives an image signal from the main processor and processes the image signal to conform to the interface specifications of the display module 11.

The memory 13 may include at least one of a non-volatile memory and a volatile memory. The memory 13 may store data information necessary for an operation of the processor 12 or the display module 11. When the processor 12 executes an application stored in the memory 13, an image data signal and/or an input control signal may be transmitted to the display module 11, and the display module 11 may process the received signal and output image information through a display screen.

The power module 14 may include a power supply module, such as a power adapter or a battery device, and a power conversion module that converts power supplied by the power supply module to generate power necessary for an operation of the electronic device 10. Power conversion by the power conversion module may include, but is not necessarily limited to, DC-to-DC conversion, AC-to-DC conversion, and DC-to-AC conversion.

The input module 15 may provide input information to the processor 12 and/or the display module 11. The input module 15 may include various sensor modules as well as physical buttons, a keyboard, and a microphone. Examples of the sensor modules may include a touch sensor, a pressure sensor, a distance sensor, a position sensor, a digitizer, a motion recognition sensor, a camera sensor, a light-receiving sensor, a photoelectric conversion sensor, and a temperature sensor, as well as biosensors, such as a blood pressure sensor, a blood sugar sensor, an electrocardiogram sensor, and a heart rate sensor.

The non-image output module 16 may receive information other than an image received from the processor 12, and may provide the information to a user. Examples of the non-image output module 16 may include a sound module, a haptic module, a light-emitting module, and may include other functional modules unique to an electronic device 10 (e.g., a cooling module of a refrigerator).

The communication module 17, which is a module responsible for transmitting and receiving information between the electronic device 10 and an external device, may include a reception unit and a transmission unit. The communication module 17 may include various wireless communication modules, such as a mobile communication module, a Wi-Fi module, and a Bluetooth module, or various wired communication modules.

At least one of the components of the electronic device 10 described above may be included in display apparatuses 1 according to the aforementioned embodiments. In addition, some of the individual modules functionally included within the electronic device 10 may be included within the display apparatus 1, and the others may be provided separately from the display apparatus. For example, the display apparatus 1 may include the display module 11, and the processor 12, the memory 13, and the power module 14 may be provided in the form of other devices within the electronic device 10 rather than the display apparatus 1. As an example, the power module 14 may be provided within the display apparatus 1, and may supply power to the processor 12 and the memory 13 provided within the electronic device 10 other than the display apparatus 1. However, embodiments are not necessarily limited to the above examples.

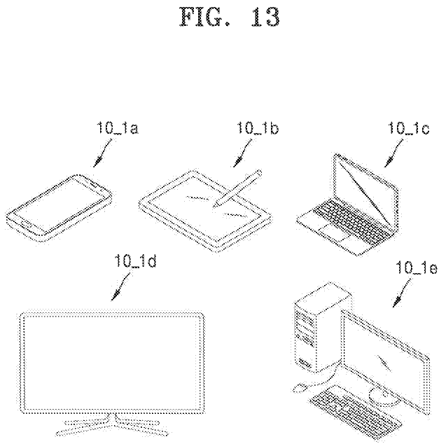

FIGS. 13 through 15 are schematic views of electronic devices according to various embodiments.

FIG. 13 illustrates, as examples of electronic devices, a smartphone 10_1a, a tablet computer 10_1b, a laptop/notebook computer 10_1c, a TV 10_1d, and a computer monitor 10_1e.

The smartphone 10_1a may include an input module, such as a touch sensor, and a communication module, in addition to a display module. The smartphone 10_1a may process information received through the communication module or other input modules, and may display the information through the display module of the display apparatus.

The tablet computer 10_1b, the laptop/notebook computer 10_1c, the TV 10_1d, and the computer monitor 10_1e may include a display module and an input module, similar to the smartphone 10_1a. In some cases, the tablet computer 10_1b, the laptop/notebook computer 10_1c, the TV 10_1d, and the computer monitor 10_1e may further include communication modules.

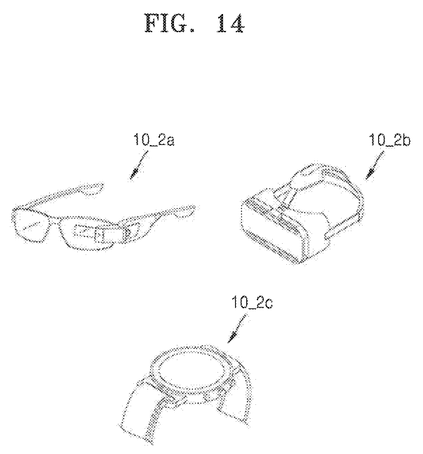

FIG. 14 illustrates a case where an electronic device including a display module is applied to a wearable electronic device. The wearable electronic device may be smart glasses 10_2a, a head mounted display 10_2b, a smart watch 10_2c, or the like.

The smart glasses 10_2a and the head mounted display 10_2b may include a display module for emitting a display image and a reflector for reflecting the emitted display image to provide a result of the reflection to the user's eyes, thereby providing a virtual reality or augmented reality screen image to the user.

The smart watch 10_2c may include a biosensor as an input device, and may provide biometric information recognized by the biosensor to the user through a display module.

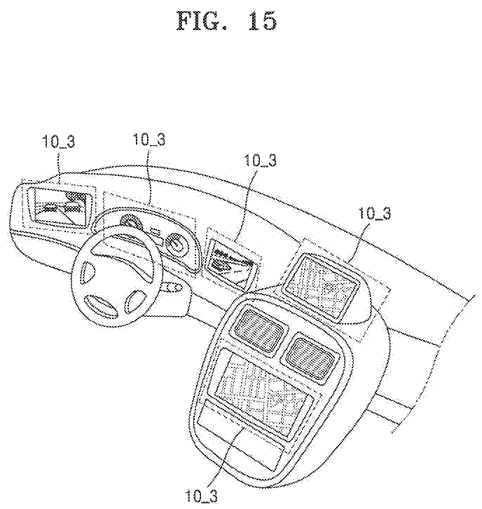

FIG. 15 illustrates a case where an electronic device including a display module is applied to a vehicle. For example, the electronic device 10_3 may be applied to dashboards, center fasciae, etc. of automobiles, or may be applied to, for example, center information displays (CIDs) disposed on the dashboards of automobiles or room mirror displays that replace the side mirrors of automobiles.

Electronic devices to which display apparatuses according to embodiments are applied may include not only devices that mainly perform screen display, such as a digital billboard, an electronic board, and a portable game console, but also various home appliances that display information through display modules, such as a refrigerator, a washing machine, a dryer, an air conditioner, and a robot vacuum cleaner. In addition, when a display module has a function of transmitting light, the display module may be applied to electronic devices, such as smart windows or transparent display apparatuses that display both a background and a displayed image. The types of electronic devices according to embodiments are not necessarily limited to those exemplified above, and application of various other electronic devices not exemplified is also possible.

According to an embodiment as described above, an electronic device including a crack detection unit for detecting a crack in a display panel may be implemented. Of course, the scope of the disclosure is not necessarily limited to these effects.

It should be understood that embodiments described herein should be considered in a descriptive sense and not necessarily for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the present disclosure.

What is claimed is:

1. A display apparatus, comprising:
a substrate comprising a display area in which a plurality of pixels are disposed and a peripheral area proximate to the display area;
first data lines disposed in the display area;
second data lines disposed between neighboring pairs of the first data lines;
a first crack detection line disposed in the peripheral area, extending along a portion of an edge of the substrate, and including a first subline and a second subline;
a first connection line electrically connected to the first subline;
a first voltage line electrically connected to the first connection line;
a second voltage line electrically connected to the second subline;
a crack detection circuit electrically connecting the first data lines to the first voltage line and electrically connecting the second data lines to the second voltage line; and
a power management circuit configured to supply a detection voltage having a negative value to the first connection line.

2. The display apparatus of claim 1,
wherein each of the plurality of pixels comprises a pixel circuit and a light-emitting diode electrically connected to the pixel circuit, and
wherein the pixel circuit comprises:
a first transistor electrically connected between a driving voltage line and the light-emitting diode;
a second transistor electrically connected between one of the first data lines and the second data lines and a gate of the first transistor;
a third transistor electrically connected between a reference voltage line and the gate of the first transistor;
a fourth transistor electrically connected between an initializing voltage line and the light-emitting diode;
a fifth transistor electrically connected between the driving voltage line and a first terminal of the first transistor;
a sixth transistor electrically connected between the light-emitting diode and a second terminal of the first transistor;
a first capacitor electrically connected between the gate of the first transistor and the second terminal of the first transistor; and
a second capacitor electrically connected between the driving voltage line and the second terminal of the first transistor.

3. The display apparatus of claim 2, wherein the first transistor is an n-type transistor.

4. The display apparatus of claim 3, wherein the fifth transistor is a p-type transistor.

5. The display apparatus of claim 4, wherein the sixth transistor is a p-type transistor.

6. The display apparatus of claim 3, wherein the first transistor is a metal oxide thin-film transistor.

7. The display apparatus of claim 6, wherein the fifth transistor and the sixth transistor are each silicon thin-film transistors.

8. The display apparatus of claim 2, wherein an initializing voltage less than or equal to the detection voltage is applied to the initializing voltage line.

9. The display apparatus of claim 2,
wherein the power management circuit is configured to supply a first reference voltage to the reference voltage line in a normal mode and to supply a second reference voltage to the reference voltage line in a crack detection mode, and
wherein the second reference voltage is greater than the first reference voltage.

10. The display apparatus of claim 1, wherein the first crack detection line has a serpentine pattern.

11. The display apparatus of claim 1,
wherein the crack detection circuit comprises:
a gate signal line configured to transmit a crack detection signal;
first detection transistors electrically connected between the first data lines and the first voltage line; and
second detection transistors electrically connected between the second data lines and the second voltage line, and
wherein a gate of each of the first detection transistors and the second detection transistors is electrically connected to the gate signal line.

12. The display apparatus of claim 1,
wherein the peripheral area comprises a bending region and a subregion spaced apart from the display area with the bending region interposed therebetween,
wherein the display apparatus further comprises:
third data lines disposed in the display area and disposed between the first data lines;
a second crack detection line disposed in the bending region and having a first end and a second end; and
a third voltage line electrically connected to the first end of the second crack detection line,
wherein the crack detection circuit is configured to electrically connect the third data lines to the third voltage line, and
wherein the power management circuit is configured to supply the detection voltage to the second end of the second crack detection line.

13. The display apparatus of claim 12,
wherein the crack detection circuit comprises:
a gate signal line configured to transmit a crack detection signal;
first detection transistors electrically connected between the first data lines and the first voltage line;
second detection transistors electrically connected between the second data lines and the second voltage line; and
third detection transistors electrically connected between the third data lines and the third voltage line, and
wherein a gate of each of the first detection transistors, the second detection transistors, and the third detection transistors is electrically connected to the gate signal line.

14. A display apparatus, comprising:
a substrate comprising a display area in which a plurality of pixels are disposed and a peripheral area proximate to the display area;
first data lines disposed in the display area;
second data lines disposed between neighboring pairs of the first data lines;
a first crack detection line disposed in the peripheral area, extending along a portion of an edge of the substrate, and including a first subline and a second subline;
a first connection line electrically connected to the first subline;
a first voltage line electrically connected to the first connection line;
a second voltage line electrically connected to the second subline; and
a crack detection circuit electrically connecting the first data lines to the first voltage line and electrically connecting the second data lines to the second voltage line,
wherein the first connection line is grounded.

15. The display apparatus of claim 14,
wherein each of the plurality of pixels comprises a pixel circuit and a light-emitting diode electrically connected to the pixel circuit, and
wherein the pixel circuit comprises:
a first transistor electrically connected between a driving voltage line and the light-emitting diode;
a second transistor electrically connected between one of the first data lines and the second data lines and a gate of the first transistor;
a third transistor electrically connected between a reference voltage line and the gate of the first transistor;
a fourth transistor electrically connected between an initializing voltage line and the light-emitting diode;
a fifth transistor electrically connected between the driving voltage line and a first terminal of the first transistor;
a sixth transistor electrically connected between the light-emitting diode and a second terminal of the first transistor;
a first capacitor electrically connected between the gate of the first transistor and the second terminal of the first transistor; and
a second capacitor electrically connected between the driving voltage line and the second terminal of the first transistor.

16. The display apparatus of claim 15, wherein the first transistor is an n-type transistor.

17. The display apparatus of claim 15, further comprising a power management circuit configured to supply a first reference voltage to the reference voltage line in a normal mode and supply a second reference voltage to the reference voltage line in a crack detection mode,
wherein the second reference voltage is greater than the first reference voltage.

18. The display apparatus of claim 14,
wherein the crack detection circuit comprises:
a gate signal line configured to transmit a crack detection signal;
first detection transistors electrically connected between the first data lines and the first voltage line; and
second detection transistors electrically connected between the second data lines and the second voltage line, and
wherein a gate of each of the first detection transistors and the second detection transistors is electrically connected to the gate signal line.

19. An electronic device, comprising:
a display apparatus configured to display an image based on an image data signal;
a memory storing an application; and
a processor configured to execute the application and transmit the image data signal and a control signal to the display apparatus,
wherein the display apparatus comprises:
a substrate comprising a display area in which a plurality of pixels are disposed and a peripheral area proximate to the display area;
first data lines disposed in the display area;
second data lines disposed between neighboring pairs of the first data lines;
a first crack detection line disposed in the peripheral area, extending along a portion of an edge of the substrate, and including a first subline and a second subline;
a first connection line electrically connected to the first subline;
a first voltage line electrically connected to the first connection line;
a second voltage line electrically connected to the second subline;
a crack detection circuit configured to electrically connect the first data lines to the first voltage line and electrically connect the second data lines to the second voltage line; and
a power management circuit configured to supply a voltage for driving the plurality of pixels, and
wherein the first connection line is grounded or supplied with a detection voltage having a negative value.

20. The electronic device of claim 19,
wherein each of the plurality of pixels comprises a pixel circuit and a light-emitting diode electrically connected to the pixel circuit,
wherein the pixel circuit comprises:
a first transistor connected between a driving voltage line and the light-emitting diode; and
a second transistor connected between one of the first data lines and the second data lines and a gate of the first transistor, and
wherein the first transistor is an n-type transistor.
